(19) United States
(12) Patent Application Publication
(10) Pub. No.: US 2025/0072114 A1
(43) Pub. Date: Feb. 27, 2025

(54) DISPLAY DEVICE

(71) Applicant: Samsung Display Co., LTD., Yongin-si (KR)

(72) Inventors: Veidhes BASRUR, Yongin-si (KR); Ki Nyeng KANG, Yongin-si (KR); Keun Kyu SONG, Yongin-si (KR); Jong Hwan CHA, Yongin-si (KR)

(73) Assignee: Samsung Display Co., LTD., Yongin-si (KR)

(21) Appl. No.: 18/766,979

(22) Filed: Jul. 9, 2024

(30) Foreign Application Priority Data
Aug. 25, 2023 (KR) 10-2023-0112265

(51) Int. Cl. H01L 27/12; H01L 25/16; H01L 33/62

(52) U.S. Cl. CPC H01L 27/124; H01L 25/167; H01L 33/62

(57) ABSTRACT

An embodiment of the disclosure provides a display device including a substrate including a display area, and a peripheral area disposed on a side of the display area, a first alignment electrode, a second alignment electrode, and a third alignment electrode that overlap the display area, are spaced apart from each other in a first direction, and extend in a second direction intersecting the first direction, light emitting elements disposed between the first alignment electrode and the second alignment electrode, and between the second alignment electrode and the third alignment electrode, and a data line overlapping the second alignment electrode in a plan view and extending in the second direction. A length of a first width of the data line in the first direction is less than or equal to a length of a second width of the second alignment electrode in the first direction.

### CROSS-REFERENCE TO RELATED APPLICATION(S)

This application claims priority to and benefits of Korean Patent Application No. 10-2023-0112265 under 35 U.S.C. § 119, filed in the Korean Intellectual Property Office on Aug. 25, 2023, the entire contents of which are incorporated herein by reference.

### BACKGROUND

### 1. Technical Field

This disclosure relates to a display device.

### 2. Description of the Related Art

Recently, as interest in an information display is increasing, research and development for display devices are continuously conducted.

### SUMMARY

An aspect of the disclosure is to provide a display device that may improve light emitting efficiency by securing light emitting elements disposed between alignment electrodes.

Aspects of the disclosure are not limited to the above-described aspect, and may be variously extended without departing from the spirit and scope of the disclosure.

An embodiment of the disclosure provides a display device that may include a substrate including a display area, and a peripheral area disposed on a side of the display area, a first alignment electrode, a second alignment electrode, and a third alignment electrode that overlap the display area, are spaced apart from each other in a first direction, and extend in a second direction intersecting the first direction, light emitting elements disposed between the first alignment electrode and the second alignment electrode, and between the second alignment electrode and the third alignment electrode, and a data line overlapping the second alignment electrode in a plan view and extending in the second direction, wherein a length of a first width of the data line in the first direction is less than or equal to a length of a second width of the second alignment electrode in the first direction.

The display device may further include a pattern electrode that overlaps the first alignment electrode, the second alignment electrode, and the third alignment electrode in a plan view and extends in the first direction.

The light emitting elements may not overlap the pattern electrode in a plan view.

The second alignment electrode and the data line may provide a first alignment signal in aligning the light emitting elements, and the first alignment electrode and the third alignment electrode may provide a second alignment signal that is different from the first alignment signal.

The display device may further include a passivation layer and a via layer sequentially disposed on the substrate, wherein the data line may be disposed between the passivation layer and the via layer, and the first alignment electrode, the second alignment electrode, and the third alignment electrode may be disposed on the via layer.

The second alignment electrode and the data line may extend from the display area to the peripheral area, and the second alignment electrode and the data line may be in direct contact through a contact portion that penetrates the via layer in the peripheral area.

The display device may further include a dummy electrode spaced apart from the second alignment electrode in the second direction in the peripheral area.

The display area may include a display element area and a pixel circuit area spaced apart from the display element area in the second direction, the first alignment electrode, the second alignment electrode, the third alignment electrode, and the light emitting elements may be disposed in the display element area, and a plurality of transistors and a storage capacitor may be disposed in the pixel circuit area.

The display device may further include a buffer layer and an interlayer insulating layer disposed between the substrate and the passivation layer, wherein a lower electrode of the storage capacitor may be disposed between the substrate and the buffer layer, an upper electrode of the storage capacitor may be disposed between the interlayer insulating layer and the passivation layer, and the pattern electrode may be disposed between the buffer layer and the interlayer insulating layer.

The display device may further include a first vertical power line that receives a first power source and extends in the second direction, a first horizontal power line electrically connected to the first vertical power line and extending in the first direction, a second vertical power line that receives a second power source and extends in the second direction, and a second horizontal power line electrically connected to the second vertical power line and extending in the first direction, wherein the first and second alignment electrodes may be disposed between the first horizontal power line and the second horizontal power line in a plan view.

The first vertical power line and the second vertical power line may be disposed on a different layer from the data line.

The storage capacitor may be spaced apart from the first horizontal power line in the second direction.

The display device may further include a scan line disposed in the pixel circuit area and extending in the first direction, wherein the storage capacitor may be disposed between the first horizontal power line and the scan line in a plan view.

A portion of the data line may overlap the first horizontal power line in a plan view.

Another embodiment of the disclosure provides a display device that may include a substrate including a first sub-pixel, and a second sub-pixel, and a display element area disposed on the substrate and including a first sub-pixel and a second sub-pixel that are spaced apart from each other in a first direction. The display element area may include a first alignment electrode, a second alignment electrode, a third alignment electrode, a fourth alignment electrode, and a fifth alignment electrode that are spaced apart from each other in the first direction, and extend in a second direction intersecting the first direction, light emitting elements disposed between the first alignment electrode and the second alignment electrode, between the second alignment electrode and the third alignment electrode, between the third alignment electrode and the fourth alignment electrode, and between the fourth alignment electrode and the fifth alignment electrode, a first data line of the first sub-pixel that overlaps the second alignment electrode in a plan view and extends in the second direction, and a second data line of the second sub-pixel that overlaps the fourth alignment electrode in a plan view and extends in the second direction, and a length of a first width of the first data line and the second data line in the first direction is less than or equal to a length of a second width of the second alignment electrode and the fourth alignment electrode in the first direction.

The display device may further include a pixel circuit area spaced apart from the display element area in the second direction and including a plurality of transistors and a storage capacitor.

The display device may further include a first pattern electrode that overlaps the first alignment electrode, the second alignment electrode, and the third alignment electrode in a plan view, and that extends in the first direction, and a second pattern electrode that is spaced apart from the first pattern electrode in the first direction, overlaps the third alignment electrode, the fourth alignment electrode, and the fifth alignment electrode, and that extends in the first direction.

In a plan view, the first pattern electrode and the second pattern electrode may not overlap the light emitting elements.

The display device may further include a pattern electrode overlapping the first alignment electrode, the second alignment electrode, the third alignment electrode, the fourth alignment electrode, and the fifth alignment electrode in a plan view and extending in the first direction, wherein in a plan view, the pattern electrode may not overlap the light emitting elements.

The first sub-pixel may include (1-1)-th light emitting elements overlapping the first alignment electrode and the second alignment electrode and (1-2)-th light emitting elements overlapping the second alignment electrode and the third alignment electrode, and the second sub-pixel may include (2-1)-th light emitting elements overlapping the third alignment electrode and the fourth alignment electrode and (2-2)-th light emitting elements overlapping the fourth alignment electrode and the fifth alignment electrode.

According to a display device according to embodiments of the disclosure, by removing (or minimizing) the components of the pixel circuit overlapping the area between the alignment electrodes, distortion of the alignment signal or limitation of the area in which the light emitting element is aligned may be minimized (or improved), by the configuration of the pixel circuit in the alignment process of the light emitting element.

However, the effects of the disclosure are not limited to the above-described effects, and may be variously extended without departing from the spirit and scope of the disclosure.

### BRIEF DESCRIPTION OF THE DRAWINGS

FIG. 1 illustrates a schematic plan view of a display device according to embodiments of the disclosure.

FIG. 2A illustrates a schematic circuit diagram of an embodiment of a pixel included in the display device of FIG. 1.

FIG. 2B illustrates a schematic circuit diagram of an embodiment of a pixel included in the display device of FIG. 1.

FIG. 3 illustrates a schematic perspective view of a light emitting element according to an embodiment.

FIG. 4 illustrates a schematic cross-sectional view of a light emitting element according to an embodiment.

FIG. 5 illustrates a schematic top plan view of an embodiment of a sub-pixel included in the display device of FIG. 1.

FIG. 6 illustrates a schematic cross-sectional view of an embodiment of the sub-pixel taken along line A-A′ of FIG. 5.

FIG. 7 illustrates a comparative example of disposition of light emitting elements according to a position of a conductive pattern of a pixel circuit.

FIG. 8 illustrates a schematic top plan view of an embodiment of a display area of FIG. 1.

FIG. 9 illustrates a schematic cross-sectional view taken along line I-I′ of FIG. 8.

FIG. 10 illustrates a schematic cross-sectional view taken along line II-II′ of FIG. 8.

FIG. 11 illustrates a schematic cross-sectional view taken along line III-III′ of FIG. 8.

FIG. 12A illustrates a schematic cross-sectional view of an embodiment of a peripheral area of FIG. 1.

FIG. 12B illustrates a schematic cross-sectional view of another embodiment of a peripheral area of FIG. 1.

FIG. 13 illustrates a schematic top plan view of another embodiment of a display area of FIG. 1.

### DETAILED DESCRIPTION OF THE EMBODIMENTS

Hereinafter, embodiments of the disclosure will be described in detail with reference to the accompanying drawings. The same reference numerals are used for the same constituent elements in the drawings, and duplicate descriptions for the same constituent elements may be omitted.

In the drawings, sizes, thicknesses, ratios, and dimensions of the elements may be exaggerated for ease of description and for clarity.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

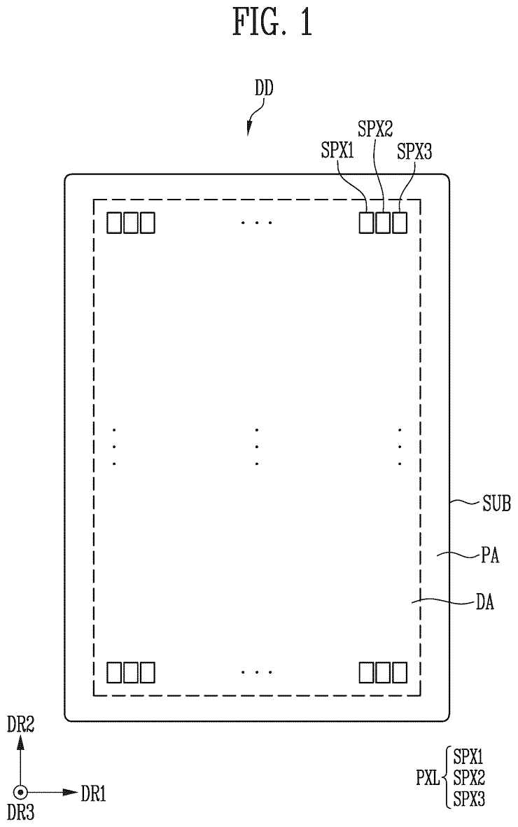

FIG. 1 illustrates a schematic plan view of a display device according to embodiments of the disclosure.

Referring to FIG. 1, a display device DD may be provided in various shapes, and as an example, may be provided in a rectangular plate shape having two pairs of sides parallel to each other, but is not limited thereto. In case that the display device DD is provided in the rectangular plate shape, a pair of sides may be provided to be longer than another pair.

At least a portion of the display device DD may have flexibility, and the display device DD may be folded at the portion having the flexibility, but is not limited thereto.

A substrate SUB may configure a base member of the display device DD, and may be a rigid or flexible substrate or film. For example, the substrate SUB may be a hard substrate made of glass or tempered glass, a flexible substrate (or a thin film) made of a plastic or metallic material, or at least one layered insulating film. The material and/or physical properties of the substrate SUB are not particularly limited.

The substrate SUB (and the display device DD) may include a display area DA for displaying an image and a peripheral area PA (or a non-display area) excluding the display area DA. The display area DA may configure a screen on which an image is displayed, and the peripheral area PA may be disposed on at least one side of the display area DA to surround the display area DA, but is not limited thereto. The peripheral area PA may surround a circumference (or edge) of the display area DA. The peripheral area PA may be a bezel area of the display device DD.

Pixels PXL may be disposed in the display area DA on the substrate SUB. The peripheral area PA may be disposed around the display area DA. The peripheral area PA may have a structure for protecting components included in the pixels PXL disposed in the display area DA, but is not limited thereto. For example, the peripheral area PA may be an area in which a driver for driving the pixels PXL and a wire portion for connecting the pixels PXL and the driver are partially provided. The wire portion may electrically connect the driver and the pixels PXL. The wire portion may provide signals to the pixels PXL, and may include signal lines respectively connected to the pixels PXL, for example, a fan-out line connected to a scan line, a data line, a light emitting control line, and the like.

The pixel PXL may include sub-pixels SPX1 to SPX3. For example, the pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be sequentially disposed in a first direction DR1. However, they are not limited thereto, and the first sub-pixel SPX1, the second sub-pixel SPX2, and the third sub-pixel SPX3 may be sequentially disposed in a second direction DR2 crossing the first direction DR1.

The first to third sub-pixels SPX1 to SPX3 may emit light in different colors. For example, the first sub-pixel SPX1 may be a red sub-pixel emitting light in red, the second sub-pixel SPX2 may be a green sub-pixel emitting light in green, and the third sub-pixel SPX3 may be a blue sub-pixel emitting light in blue. However, the color, type, and/or number of the sub-pixels configuring the pixel PXL are not particularly limited, and for example, the color of light emitted by each of the sub-pixels SPX1 to SPX3 may be variously changed.

Multiple pixels PXL may be provided to be arranged in a matrix format along a row extending in the first direction DR1 and a column extending in the second direction DR2. The arrangement form of the pixels PXL is not particularly limited, and in case that multiple pixels PXL are provided, they may be provided to have different areas (or sizes). For example, in the case in which the pixels PXL have different colors of emitted light, the pixels PXL for each color may be provided in different areas (or sizes) or in different shapes.

The driver may provide a predetermined or selected signal and a predetermined or selected power source to each pixel PXL through the wire portion, thereby controlling driving of the pixel PXL.

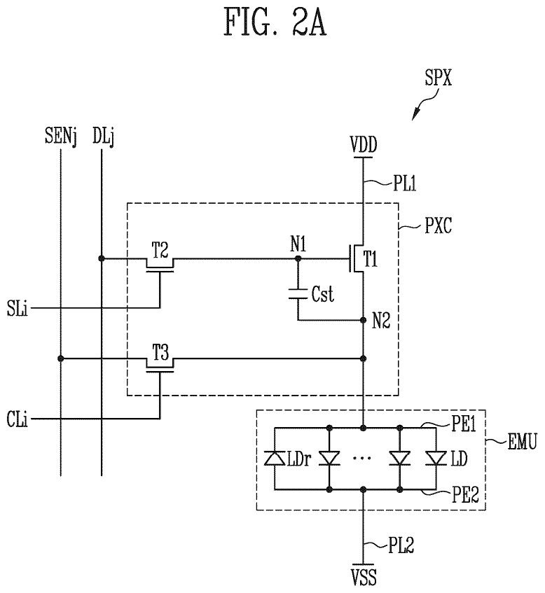

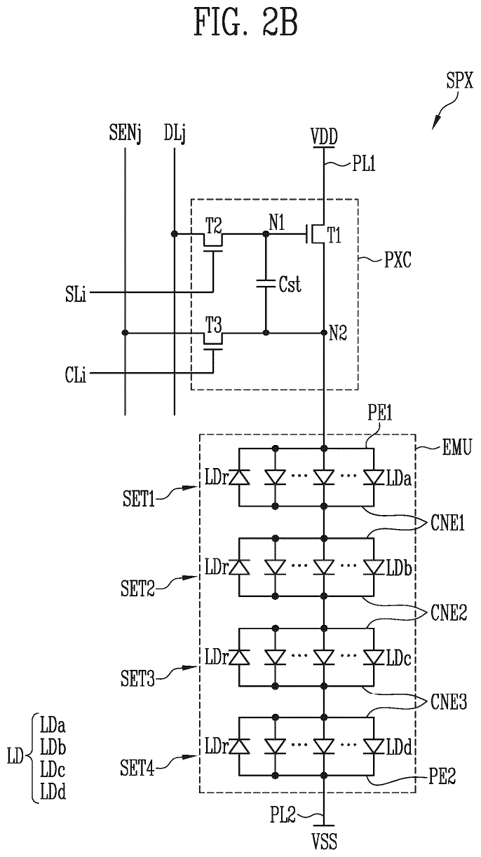

FIG. 2A illustrates a schematic circuit diagram of an embodiment of a pixel included in the display device of FIG. 1. FIG. 2B illustrates a schematic circuit diagram of an embodiment of a pixel included in the display device of FIG. 1.

FIG. 2A and FIG. 2B illustrate the electrical connection relationship of constituent elements included in each of the sub-pixels SPX1 to SPX3 that may be applied to an active matrix display device, according to an embodiment. However, the connection relationship of the constituent elements of each of the sub-pixels SPX1 to SPX3 is not limited thereto. In the following embodiment, the first sub-pixel SPX1, the second sub-pixel SPX2, and the third sub-pixel SPX3 may each be referred to as a sub-pixel SPX.

Referring to FIG. 1, FIG. 2A, and FIG. 2B, the pixel SPX may include a light emitting portion EMU (or light emitting unit) that generates light with luminance corresponding to a data signal. The sub-pixel SPX may selectively further include a pixel circuit PXC for driving the light emitting portion EMU.

In some embodiments, the light emitting portion EMU may include multiple light emitting elements LD connected in parallel between a first power line PL1 and a second power line PL2. The first power line PL1 may be connected to a first driving power source VDD to be applied with a voltage of the first driving power source VDD, and the second power line PL2 may be connected to a second driving power source VSS to be applied with a voltage of the second driving power source VSS.

For example, the light emitting portion EMU may include a first pixel electrode PE1 connected to the first power source VDD via the pixel circuit PXC and the first power line PL1, a second pixel electrode PE2 connected to the second power source VSS through the second power line PL2, and multiple light emitting elements LD connected in parallel in a same direction between the first and second electrodes PE1 and PE2. In an embodiment, the first pixel electrode PE1 may be an anode (or anode electrode), and the second pixel electrode PE2 may be a cathode (or cathode electrode).

Each of the light emitting elements LD included in the light emitting portion EMU may include a first end portion connected to the first driving power source VDD through the first pixel electrode PE1 and a second end portion connected to the second driving power source VSS through the second pixel electrode PE2. The first driving power source VDD and the second driving power source VSS may have different potentials. For example, the first driving power source VDD may be set as a high potential power source, and the second driving power source VSS may be set as a low potential power source. A potential difference between the first and second driving power sources VDD and VSS may be set to be equal to or higher than a threshold voltage of the light emitting elements LD during a light emitting period of each sub-pixel SPX.

As described above, respective light emitting elements LD connected in parallel in a same direction (for example, a forward direction) between the first pixel electrode PE1 and the second pixel electrode PE2 supplied with voltages of different power sources may form respective effective light sources.

The light emitting elements LD of the light emitting portion EMU may emit light with luminance corresponding to a driving current supplied through the corresponding pixel circuit PXC. For example, during each frame period, the pixel circuit PXC may supply a driving current corresponding to a grayscale value of corresponding frame data of the pixel circuit PXC to the light emitting portion EMU. The driving current supplied to the light emitting portion EMU may be divided to flow in each of the light emitting elements LD. Accordingly, while each light emitting element LD emits light with a luminance corresponding to the current flowing therein, the light emitting portion EMU may emit light having a luminance corresponding to the driving current.

In an above-described embodiment, although the structure in which both end portions of the light emitting elements LD are connected to in a same direction between the first and second driving power sources VDD and VSS has been described, the disclosure is not limited thereto. In some embodiments, the light emitting portion EMU may further include at least one ineffective light source, for example, a reverse light emitting element LDr, in addition to the light emitting elements LD forming respective effective light sources. The reverse light emitting element LDr may be connected in parallel between the first and second pixel electrodes PE1 and PE2 together with the light emitting elements LD forming the effective light sources, but may be connected between the first and second pixel electrodes PE1 and PE2 in the opposite direction with respect to the light emitting elements LD. The reverse light emitting element LDr maintains an inactive state even in case that a predetermined or selected driving voltage (for example, a driving voltage in the forward direction) is applied between the first and second pixel electrodes PE1 and PE2, thus a current does not substantially flow in the reverse light emitting element.

The pixel circuit PXC may be connected to a scan line SLi and a data line DLj of the sub-pixel SPX. The pixel circuit PXC may be connected to a control line CLi and a sensing line SENj of the sub-pixel SPX. For example, in case that the sub-pixel SPX is disposed to an i-th row and a j-th column of the display area DA, the pixel circuit PXC of the sub-pixel SPX may be connected to the i-th scan line SLi, the j-th data line DLj, the i-th control line CLi, and the j-th sensing line SENj of the display area DA. In some embodiments, the control line CLi may be connected to the scan line SLi, or may be the scan line SLi.

The pixel circuit PXC may include transistors T1 to T3 and a storage capacitor Cst (or capacitor).

The first transistor T1 may be a driving transistor for controlling a driving current applied to the light emitting portion EMU, and may be connected between the first driving power source VDD and the light emitting portion EMU. Specifically, a first terminal (or first transistor electrode) of the first transistor T1 may be electrically connected to the first driving power source VDD through the first power line PL1, a second terminal (or second transistor electrode) of the first transistor T1 may be electrically connected to a second node N2, and a gate electrode of the first transistor T1 may be electrically connected to a first node N1. The first transistor T1 may control an amount of the driving current applied to the light emitting portion EMU from the first driving power source VDD through the second node N2 according to a voltage applied to the first node N1. In an embodiment, the first terminal of the first transistor T1 may be a drain electrode, and the second terminal of the first transistor T1 may be a source electrode, but the disclosure is not limited thereto. In some embodiments, the first terminal thereof may be a source electrode, and the second terminal thereof may be a drain electrode.

The second transistor T2 may be a switching transistor that selects the sub-pixel SPX in response to a scan signal and activates the sub-pixel SPX, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 are different terminals, and for example, in case that the first terminal is a drain electrode, the second terminal may be a source electrode.

In case that a scan signal of a gate-on voltage (for example, a high level voltage) is supplied from the scan line SLi, the second transistor T2 may be turned on to electrically connect the data line DLj and the first node N1. The first node N1 may be a point at which the second terminal of the second transistor T2 is connected to the gate electrode of the first transistor T1, and the second transistor T2 may transmit a data signal to the gate electrode of the first transistor T1.

A first terminal of the third transistor T3 may be connected to the sensing line SENj, a second terminal of the third transistor T3 may be connected to the second terminal of the first transistor T1, and a gate electrode of the third transistor T3 may be connected to the control line CLi. An initialization power source may be applied to the sensing line SENj. The third transistor T3 may be an initialization transistor capable of initializing the second node N2, and in case that a sensing control signal is supplied from the control line CLi, the third transistor T3 may be turned on to transmit a voltage of the initialization power source to the second node N2. Accordingly, a second storage electrode of the storage capacitor Cst electrically connected to the second node N2 may be initialized. In some embodiments, the third transistor T3 connects the first transistor T1 to the sensing line SENj, so that it may obtain a sensing signal through the sensing line SENj, and may detect a characteristic of the sub-pixel SPX in addition to a threshold voltage of the first transistor T1 by using the sensing signal. Information on the characteristic of the sub-pixel SPX may be used to convert image data so that a characteristic deviation between the sub-pixels SPX may be compensated.

The storage capacitor Cst may be formed between the first node N1 and the second node N2, or may be electrically connected between the first node N1 and the second node N2. The storage capacitor Cst may be charged with a data voltage corresponding to the data signal supplied to the first node N1 during a frame period. Accordingly, the storage capacitor Cst may store a voltage corresponding to a difference between a voltage of the gate electrode of the first transistor T1 and a voltage of the second node N2.

The light emitting portion EMU may be configured to include at least one serial stage including multiple light emitting elements LD electrically connected in parallel to each other.

In an embodiment, the light emitting portion EMU may be configured in a series/parallel mixed structure. For example, as shown in FIG. 2B, the light emitting portion EMU may be configured to include a first series stage SET1, a second series stage SET2, a third series stage SET3, and a fourth series stage SET4. The number of the series stages included in the light emitting portion EMU may be variously changed, and for example, the light emitting portion EMU may include 1, 2, 3, or 5 or more series stages.

The light emitting portion EMU may include the first series stage SET1, the second series stage SET2, the third series stage SET3, and the fourth series stage SET4 sequentially connected between the first driving power source VDD and the second driving power source VSS.

The first serial stage SET1 (or first stage) may include a first pixel electrode PE1 and a first middle electrode CNE1, and it may include at least one first light emitting element LDa connected between the first pixel electrode PE1 and the first middle electrode CTE1. The first serial stage SET1 may further include a reverse direction light emitting element LDr connected to the first light emitting element LDa in an opposite direction between the first pixel electrode PE1 and the first middle electrode CNE1.

The second serial stage SET2 (or second stage) may include a first middle electrode CNE1 and a second middle electrode CNE2, and it may include at least one second light emitting element LDb connected between the first middle electrode CNE1 and the second middle electrode CTE2. The second serial stage SET2 may further include a reverse direction light emitting element LDr connected to the second light emitting element LDb in an opposite direction between the first middle electrode CNE1 and the second middle electrode CNE2.

The third serial stage SET3 (or third stage) may include a second middle electrode CNE2 and a third middle electrode CNE3, and it may include at least one third light emitting element LDc connected between the second middle electrode CNE2 and the third middle electrode CTE3. The third serial stage SET3 may further include a reverse direction light emitting element LDr connected to the third light emitting element LDc in an opposite direction between the second middle electrode CNE2 and the third middle electrode CNE3.

The fourth serial stage SET4 (or fourth stage) may include a third middle electrode CNE3 and a second pixel electrode PE2, and it may include at least one second light emitting element LDd connected between the third middle electrode CNE3 and the second pixel electrode PE2. The fourth serial stage SET4 may further include a reverse direction light emitting element LDr connected to the fourth light emitting element LDd in an opposite direction between the third middle electrode CNE3 and the second pixel electrode PE2. The terms pixel electrode and middle electrode are only expressions for distinguishing electrodes, and the corresponding configuration (for example, electrodes) is not limited by the terms.

As described above, the light emitting portion EMU of the sub-pixel SPX including the serial stages SET1 to SET4 (or the light emitting elements LD) connected in a series/parallel mixed structure may readily adjust a driving current/voltage condition according to an applied product specification.

Particularly, the light emitting portion EMU of the sub-pixel SPX including the series stages SET1 to SET4 may reduce the driving current compared to a light emitting portion in which the light emitting elements LD are only connected in parallel. In other words, the light emitting portion EMU of the sub-pixel SPX including the series stages SET1 to SET4 may emit light with higher luminance for the same driving current.

The light emitting portion EMU of the sub-pixel SPX including the series ends SET1 to SET4 may reduce the driving voltage applied to both ends of the light emitting portion EMU compared to a light emitting portion with a structure in which a same number of light emitting elements LD are all connected in series.

In FIG. 2A and FIG. 2B, the transistors T1 to T3 included in the pixel circuit PXC are all shown as n-type transistors, but the transistors are not necessarily limited thereto. For example, at least one of the transistors T1 to T3 may be changed to a p-type transistor.

The structure and driving method of the sub-pixel SPX may be variously changed. For example, the pixel circuit PXC may be configured as a pixel circuit having various structures and/or driving methods in addition to those of the embodiments shown in FIG. 2A and FIG. 2B.

For example, the pixel circuit PXC may not include the third transistor T3. The pixel circuit PXC may further include other circuit elements such as a compensation transistor for compensating for a threshold voltage of the first transistor T1, an initialization transistor for initializing the voltage of the first node N1 and/or of the first pixel electrode PE1, a light emission control transistor for controlling a period in which a driving current is supplied to the light emitting portion EMU, and/or a boosting capacitor for boosting the voltage of the first node N1.

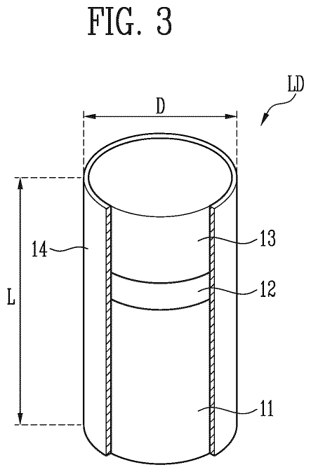

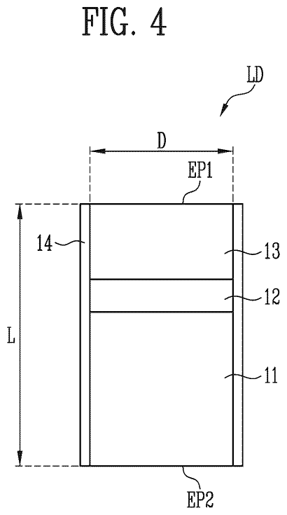

FIG. 3 illustrates a schematic perspective view of a light emitting element according to an embodiment. FIG. 4 illustrates a schematic cross-sectional view of a light emitting element according to an embodiment.

A type and/or shape of the light emitting element LD are not limited to the embodiments shown in FIG. 3 and FIG. 4.

Referring to FIG. 3 and FIG. 4, the light emitting element LD may include a first semiconductor layer 11, a second semiconductor layer 13, and an active layer 12 interposed between the first and second semiconductor layers 11 and 13. For example, the light emitting element LD may be implemented as a stacked light emitting body (or a stacked pattern) in which the first semiconductor layer 11, the active layer 12, and the second semiconductor layer 13 are stacked on each other.

The light emitting element LD may be provided to have a shape extending in a direction. In case that an extending direction of the light emitting element LD is a length direction, the light emitting element LD may include the first end portion EP1 and the second end portion EP2 along the length direction. One of the first semiconductor layer 11 and the second semiconductor layer 13 may be positioned on the first end portion EP1 of the light emitting element LD, and another of the first semiconductor layer 11 and the second semiconductor layer 13 may be positioned on the second end portion EP2 of the light emitting element LD. For example, the second semiconductor layer 13 may be positioned on the first end portion EP1 of the light emitting element LD, and the first semiconductor layer 11 may be positioned on the second end portion EP2 of the corresponding light emitting element LD.

The light emitting element LD may be provided in various shapes. As an example, the light emitting element LD may have a rod-like shape, bar-like shape, or pillar shape that is long (or an aspect ratio larger than 1) in a length direction as shown in FIG. 3. As another example, the light emitting element LD may have a rod-like shape, bar-like shape, or pillar shape that is short (or an aspect ratio smaller than 1) in a length direction. As another example, the light emitting element LD may have a rod-like shape, bar-like shape, or pillar shape that has an aspect ratio of 1.

For example, the light emitting element LD may include a light emitting diode (LED) manufactured in an ultra-small size having a diameter D and/or a length L of nano scale (or nano meter) to micro scale (or micrometer).

In case that the light emitting LD is long in a length direction (for example, an aspect ratio is larger than 1), the diameter D of the light emitting element LD may be about 0.5 m to about 6 m, and the length L thereof may be about 1 m to about 10 m. However, the diameter D and the length L of the light emitting element LD are not limited thereto, and the size of the light emitting element LD may be changed so that the light emitting element LD meets requirements (or design conditions) of a lighting device or a self-luminous display device to which the light emitting element LD is applied.

For example, the first semiconductor layer 11 may include at least one n-type semiconductor layer. For example, the first semiconductor layer 11 may include a semiconductor material of at least one of InAlGaN, GaN, AlGaN, InGaN, AlN, and InN, and may be a n-type semiconductor layer doped with a first conductive dopant (or n-type dopant) such as Si, Ge, Sn, or the like. However, the material included in the first semiconductor layer 11 is not limited thereto, and the first semiconductor layer 11 may be made of various materials. The first semiconductor layer 11 may include an upper surface contacting the active layer 12 along the length direction of the light emitting element LD and a lower surface exposed to the outside. The lower surface of the first semiconductor layer 11 may be an end portion (or lower end portion) of the light emitting element LD.

The active layer 12 may be disposed on the first semiconductor layer 11, and may be formed to have a single or multi-quantum well structure. For example, in case that the active layer 12 is formed of a multi-quantum well structure, the active layer 12 may have a structure in which a barrier layer (not shown), a strain reinforcing layer, and a well layer, which consist of one unit, are periodically and repeatedly stacked on each other. Since the strain reinforcing layer has a smaller lattice constant than that of the barrier layer, it may further reinforce strain applied to the well layer, for example, compressive strain. However, the structure of the active layer 12 is not limited to an above-described embodiment.

The active layer 12 may emit light having a wavelength of about 400 nm to about 900 nm, and may have a double hetero-structure. In an embodiment, a clad layer (not shown) doped with a conductive dopant may be formed above and/or below the active layer 12 along the length direction of the light emitting element LD. For example, the clad layer may be formed as an AlGaN layer or an InAlGaN layer. In some embodiments, a material such as AlGaN and InAlGaN may be used to form the active layer 12, and in addition, various materials may form the active layer 12. The active layer 12 may include the first surface contacting the first semiconductor layer 11 and the second surface contacting the second semiconductor layer 13.

In case that an electric field of a predetermined or selected voltage or more is applied to respective end portions of the light emitting element LD, the light emitting element LD emits light while electron-hole pairs are combined in the active layer 12. By controlling the light emission of the light emitting element LD by using this principle, the light emitting element LD may be used as a light source (or light emitting source) for various light emitting devices in addition to pixels of a display device.

The second semiconductor layer 13 may be disposed on the second surface of the active layer 12, and may include a semiconductor layer of a type different from that of the first semiconductor layer 11. For example, the second semiconductor layer 13 may include at least one p-type semiconductor layer. For example, the second semiconductor layer 13 may include at least one semiconductor material of InAlGaN, GaN, AlGaN, InGaN, AlN, and InN, and may include a p-type semiconductor layer doped with a second conductive dopant (or p-type dopant) such as Mg, Zn, Ca, Sr, and Ba. However, the material included in the second semiconductor layer 13 is not limited thereto, and the second semiconductor layer 13 may be formed of various materials. The second semiconductor layer 13 may include a lower surface contacting the second surface of the active layer 12 along the length direction of the light emitting element LD and an upper surface exposed to the outside. Here, the upper surface of the second semiconductor layer 13 may be another end portion (or upper end portion) of the light emitting element LD.

In an embodiment, the first semiconductor layer 11 and the second semiconductor layer 13 may have different thicknesses from each other in the length direction of the light emitting element LD. For example, the first semiconductor layer 11 may have a relatively thicker thickness than that of the second semiconductor layer 13 along the length direction of the light emitting element LD. Accordingly, the active layer 12 of the light emitting element LD may be disposed closer to the upper surface of the second semiconductor layer 13 than the lower surface of the first semiconductor layer 11.

It is illustrated that each of the first semiconductor layer 11 and the second semiconductor layer 13 is formed as one layer, but the disclosure is not limited thereto. In an embodiment, each of the first semiconductor layer 11 and the second semiconductor layer 13 may further include at least one layer, for example, a cladding layer and/or a tensile strain barrier reducing (TSBR) layer according to the material of the active layer 12. The TSBR layer may be a strain reducing layer disposed between semiconductor layers having different lattice structures and serving as a buffer to reduce a difference in lattice constant. The TSBR layer may be formed of a p-type semiconductor layer such as p-GaInP, p-AlInP, or p-AlGaInP, but is not limited thereto.

In some embodiments, the light emitting element LD may further include a contact electrode (hereinafter referred to as a “first contact electrode”) (not shown) disposed on the second semiconductor layer 13 in addition to the first semiconductor layer 11, the active layer 12, and second semiconductor layer 13 described above. In another embodiment, another contact electrode (not shown, hereinafter referred to as a “second contact electrode”) disposed on an end of the first semiconductor layer 11 may be further included.

Each of the first and second contact electrodes may be an ohmic contact electrode, but the disclosure is not limited thereto. In some embodiments, the first and second contact electrodes may be a Schottky contact electrode. The first and second contact electrodes may include a conductive material. For example, the first and second contact electrodes may include an opaque metal in which chromium (Cr), titanium (Ti), aluminum (Al), gold (Au), nickel (Ni), and an oxide or alloy thereof are used alone or in combination, but are not limited thereto. In some embodiments, the first and second contact electrodes may include a transparent conductive oxide such as an indium tin oxide (ITO), an indium zinc oxide (IZO), a zinc oxide (ZnOₓ), an indium gallium zinc oxide (IGZO), and an indium tin zinc oxide (ITZO). Here, the zinc oxide (ZnOₓ) may be a zinc oxide (ZnO) and/or a zinc peroxide (ZnO₂).

Materials included in the first and second contact electrodes may be same or different from each other. The first and second contact electrodes may be substantially transparent or translucent. Accordingly, light generated by the light emitting element LD may transmit through each of the first and the second contact electrodes to be outputted to the outside of the light emitting element LD. In some embodiments, in case that the light generated by the light emitting element LD does not transmit through the first and second contact electrodes and is discharged to the outside through a region except for respective end portions of the light emitting element LD, the first and second contact electrodes may include an opaque metal.

In an embodiment, the light emitting element LD may further include an insulating film 14 (or an insulating film). However, in some embodiments, the insulating film 14 may be omitted, or it may be provided so as to cover only some of the first semiconductor layer 11, the active layer 12, and the second semiconductor layer 13.

The insulating film 14 may prevent an electrical short circuit that may occur in case that the active layer 12 contacts conductive materials other than the first and second semiconductor layers 11 and 13. The insulating film 14 may minimize surface defects of the light emitting element LD to improve lifespan and luminous efficiency of the light emitting element LD. In case that multiple light emitting elements LD are closely disposed, the insulating film 14 may prevent unwanted short circuits that may occur between the light emitting elements LD. As long as the active layer 12 may prevent a short circuit with an external conductive material from being caused, whether or not the insulating film 14 is provided is not limited.

The insulating film 14 may be provided in a form that entirely surrounds an outer circumferential surface of a light emitting stacked structure including the first semiconductor layer 11, the active layer 12, and the second semiconductor layer 13.

In an above-described embodiment, the structure in which the insulating film 14 entirely surrounds the outer circumferential surfaces of the first semiconductor layer 11, the active layer 12, and the second semiconductor layer 13 is described, but the disclosure is not limited thereto. In some embodiments, in case that the light emitting element LD includes the first contact electrode, the insulating film 14 may entirely surround the outer circumferential surface of each of the first semiconductor layer 11, the active layer 12, the second semiconductor layer 13, and the first contact electrode. In another embodiment, the insulating film 14 may not entirely surround the outer circumferential surface of the first contact electrode, or may only surround a portion of the outer circumferential surface of the first contact electrode and may not surround the remaining portion of the external circumferential surface of the first contact electrode. In some embodiments, in case that the first contact electrode is disposed at another end portion (or an upper end portion) of the light emitting element LD and the second contact electrode is disposed at an end portion (or a lower end portion) of the light emitting element LD, the insulating film 14 may expose at least one region of each of the first and second contact electrodes.

The insulating film 14 may include a transparent insulating material. For example, the insulating film 14 may include at least one of insulating materials of a silicon oxide (SiOₓ), a silicon nitride (SiNₓ), a silicon oxynitride (SiOₓN_{y}), an aluminum oxide (AlOₓ), a titanium oxide (TiOₓ), a hafnium oxide (HfOₓ), a titanium strontium oxide (SrTiOₓ), a cobalt oxide (CoₓO_{y}), a magnesium oxide (MgO), a zinc oxide (ZnOₓ), a ruthenium oxide (RuOₓ), a nickel oxide (NiO), a tungsten oxide (WOₓ), tantalum oxide (TaOₓ), a gadolinium oxide (GdOₓ), a zirconium oxide (ZrOₓ), a gallium oxide (GaOₓ), a vanadium oxide (VₓO_{y}), ZnO:Al, ZnO:B, InₓO_{y}:H, a niobium oxide (NbₓO_{y}), a fluorinated magnesium (MgFₓ), a fluorinated aluminum (AlFₓ), an alucone polymer film, a titanium nitride (TiN), a tantalum nitride (TaN), an aluminum nitride (AlNₓ), a gallium nitride (GaN), a tungsten nitride (WN), a hafnium nitride (HfN), a niobium nitride (NbN), gadolinium nitride (GdN), a zirconium nitride (ZrN), and a vanadium nitride (VN), but the disclosure is not limited thereto, and various materials having insulating properties may be used as the material of the insulation film 14.

The insulating film 14 may be provided in a form of a single layer or in a form of a multilayer including a double layer. For example, in case that the insulating film 14 is configured as a double layer including a first insulating layer and a second insulating layer that are stacked on each other, the first insulating layer and the second insulating layer may be made of different materials (or substances), and may be formed by different processes. In some embodiments, the first insulating layer and the second insulating layer may include a same material to be formed by a continuous process.

The light emitting element LD may be implemented in a light emitting pattern having a core-shell structure. An above-described first semiconductor layer 11 may be positioned at a core, for example, a middle (or center) of the light emitting element LD, and the active layer 12 may surround the outer circumferential surface of the first semiconductor layer 11, and the second semiconductor layer 13 may be provided and/or formed to surround the active layer 12. The light emitting element LD may further include a contact electrode (not shown) surrounding at least one side of the second semiconductor layer 13. In some embodiments, the light emitting element LD may further include the insulating film 14 provided on the outer circumferential surface of the light emitting pattern having a core-shell structure and including a transparent insulating material. The light emitting element LD implemented in the light emitting pattern having the core-shell structure may be manufactured by a growth method.

An above-described light emitting element LD may be used as a light emitting source (or light source) for various display devices. The light emitting element LD may be manufactured through a surface treatment process. For example, in case that multiple light emitting elements LD are mixed with a fluid solution (or a solvent) and supplied to each pixel area (for example, a light emitting area of each pixel or a light emitting area of each sub pixel), each light emitting element LD may be surface-treated so that the light emitting elements LD may be non-uniformly aggregated in the solution and may be uniformly sprayed.

A light emitting unit (or light emitting device) including an above-described light emitting element LD may be used in various types of electronic devices that require a display device and a light source. For example, in case that multiple light emitting elements LD are disposed in a pixel area of each pixel of a display panel, the light emitting elements LD may be used as a light source of each pixel. However, an application field of the light emitting element LD is not limited to the above-described example. For example, the light emitting element LD may be used in other types of electronic devices that require a light source, such as a lighting device.

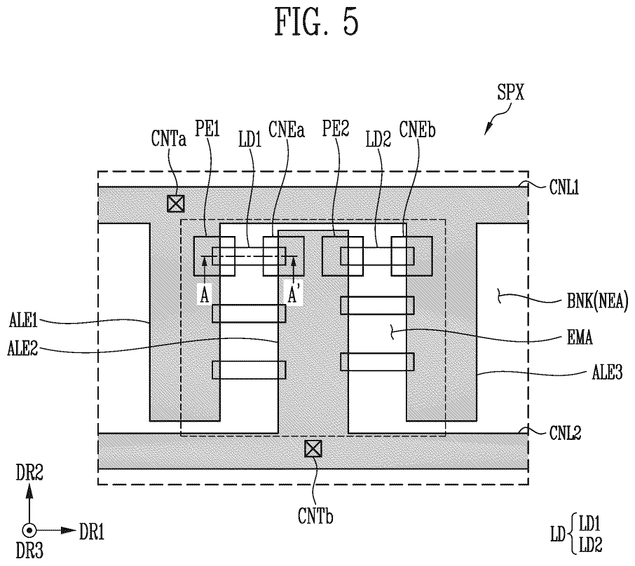

FIG. 5 illustrates a schematic top plan view of an embodiment of a sub-pixel included in the display device of FIG. 1. FIG. 5 is a diagram for explaining some components included in the sub-pixel SPX.

Referring to FIG. 5, the sub-pixel SPX may include a bank BNK, first and second pixel electrodes PE1 and PE2, (1-1)-th and (1-2)-th middle electrodes CNEa and CNEb, first to third alignment electrodes ALE1 to ALE3, first and second connection electrodes CNL1 and CNL2, and light emitting elements LD.

The bank BNK may partition sub-pixels SPX, and a light emitting area EMA may correspond to an opening defined by the bank BNK. In an embodiment, the bank BNK may form a space in which fluid may be accommodated. For example, during the manufacturing process, ink including the light emitting element LD may be provided in the space in which the fluid may be accommodated.

A non-light emitting area NEA may be an area substantially corresponding to the bank BNK. In a plan view, the bank BNK may surround the light emitting area EMA.

The sub-pixel SPX may include the first to third alignment electrodes ALE1 to ALE3. In an embodiment, the first to third alignment electrodes ALE1 to ALE3 may function as an electrode for aligning the light emitting element LD and as an electrode for applying a predetermined or selected voltage.

The first to third alignment electrodes ALE1 to ALE3 may extend in a second direction DR2, and may be spaced apart from each other in a first direction DR1.

The first connection electrode CNL1 may be integrally formed by being disposed in a same layer as the first alignment electrode ALE1 and the third alignment electrode ALE3. The second connection electrode CNL2 may be integrally formed by being disposed in a same layer as the second alignment electrode ALE2.

The first to third alignment electrodes ALE1 to ALE3 may function as alignment electrodes for the light emitting elements LD. For example, the light emitting elements LD may be arranged based on electrical signals provided to the first to third alignment electrodes ALE1 to ALE3.

In an embodiment, the first to third alignment electrodes ALE1 to ALE3 may be supplied (or provided) with a first alignment signal or a second alignment signal, respectively, in a process step (hereinafter, an alignment process) in which the light emitting elements LD are aligned.

In an embodiment, the first alignment signal may be applied to the first alignment electrode ALE1 and the third alignment electrode ALE3. The second alignment signal may be applied to the second alignment electrode ALE2 disposed between the first alignment electrode ALE1 and the third alignment electrode ALE3. In an embodiment, the first to third alignment electrodes ALE1 to ALE3 may be connected to a lower first signal line through a (1-1)-th contact portion CNTa formed on the first connection electrode CNL1, and in the alignment process, the first alignment signal may be provided to the first and third alignment electrodes ALE1 and ALE3 through the first signal line. In an embodiment, the second alignment signal may be provided to the second alignment electrode ALE2 through a (1-2)-th contact portion CNTb formed on the second connection electrode CNL2.

The light emitting elements LD may be arranged in a parallel structure along the second direction DR2. The arrangement structure of the light emitting elements LD is not limited thereto.

The light emitting elements LD may be disposed between the first to third alignment electrodes ALE1 to ALE3 in a plan view. In an embodiment, the light emitting elements LD may include the (1-1)-th light emitting element LD1 and the (1-2)-th light emitting element LD2. In an embodiment, the (1-1)-th light emitting elements LD1 may be disposed between (or on) the first and second alignment electrodes ALE1 and ALE2. The (1-2)-th light emitting elements LD2 may be disposed between (or on) the second and third alignment electrodes ALE2 and ALE3.

The first pixel electrode PE1 may be disposed on the first alignment electrode ALE1 in a plan view to be electrically connected to an end portion of the (1-1)-th light emitting elements LD1. The (1-1)-th middle electrode CNEa may be disposed on the second alignment electrode ALE2 to be electrically connected to another end portion of the (1-1)-th light emitting elements LD1. In an embodiment, the (1-1)-th middle electrode CNEa may correspond to the first middle electrode CNE1 shown in FIG. 2B. The first pixel electrode PE1 and the (1-1) middle electrode CNEa may cover the end portions of the light emitting elements adjacent to the first connection electrode CNL1 among the (1-1)-th light emitting elements LD1 disposed between the first and second alignment electrodes ALE1 and ALE2, and the end portions of the light emitting elements adjacent to the second connection electrode CNL2 among the (1-1)-th light emitting elements LD1 may be covered by separate middle electrodes (for example, the first and second middle electrodes CNE1 and CNE2 of FIG. 2B) that are distinguished from the first pixel electrode PE1 and the (1-1)-th middle electrode CNEa.

The second pixel electrode PE2 may be disposed on the second alignment electrode ALE2 in a plan view to be electrically connected to an end portion of the (1-2)-th light emitting element LD2. The (1-2)-th middle electrode CNEb may be disposed on the third alignment electrode ALE3 to be electrically connected to another end portion of the (1-2)-th light emitting element LD2. In an embodiment, the (1-2)-th middle electrode CNEb may correspond to the third middle electrode CNE3 shown in FIG. 2B. The second pixel electrode PE2 and the (1-2) middle electrode CNEb may cover the end portions of the light emitting elements adjacent to the first connection electrode CNL1 among the (1-2)-th light emitting elements LD2 disposed between the second and third alignment electrodes ALE2 and ALE3, and the end portions of the light emitting elements adjacent to the second connection electrode CNL2 among the (1-2)-th light emitting elements LD2 may be covered by separate middle electrodes (for example, the second and third middle electrodes CNE2 and CNE3 of FIG. 2B) that are distinguished from the second pixel electrode PE2 and the (1-2)-th middle electrode CNEb.

The first to third alignment electrodes ALE1 to ALE3 may be electrically connected to a pixel circuit (for example, the pixel circuit PXC of FIG. 2A or FIG. 2B) and/or a power line. For example, the first and third alignment electrodes ALE1, and ALE3 may be electrically connected to the pixel circuit PXC and/or the first power line (for example, the first power line PL1 of FIG. 2A or FIG. 2B) through the (1-1)-th contact portion CNTa formed on the first connection electrode CNL1. The second alignment electrode ALE2 may be electrically connected to the pixel circuit PXC and/or the second power line (for example, the second power line PL2 of FIG. 2A or FIG. 2B) through the (1-2)-th contact portion CNTb formed on the second connection electrode CNL2.

The first pixel electrode PE1 may be directly connected to the first power line PL1 through a separate contact portion (not shown) that is distinct from the (1-1)-th contact portion CNTa, and the second pixel electrode PE2 may be directly connected to the second power line PL2 through a separate contact portion (not shown) that is distinct from the (1-2)-th contact portion CNTb, but are not limited thereto. The first pixel electrode PE1 may be connected to the first power line PL1 through the first connection electrode CNL1, and the second pixel electrode PE2 may be connected to the second power line PL2 through the second connection electrode CNL2.

In case that the light emitting elements LD are provided in the sub-pixel SPX, the light emitting elements LD may configure an effective light source in case that the light emitting elements LD are arranged in the forward direction between the first and second alignment electrodes ALE1 and ALE2 or between the second and third alignment electrodes ALE2 and ALE3, and the light emitting elements LD may configure an ineffective light source in case arranged in the reverse direction. In an embodiment, in order to increase the light emitting efficiency of the sub-pixel SPX, it may be desirable to secure enough light emitting elements LD disposed in the forward direction between the first and second alignment electrodes ALE1 and ALE2 or between the second and third alignment electrodes ALE2 and ALE3.

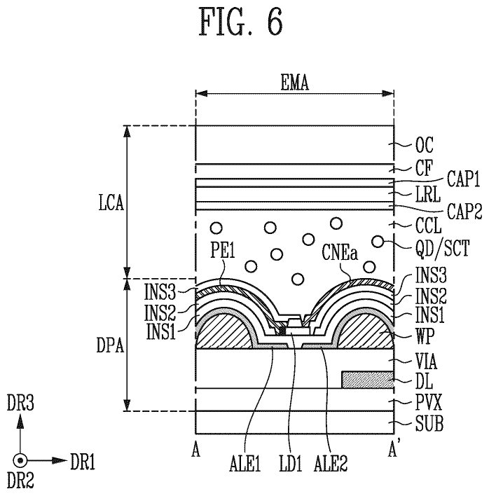

FIG. 6 illustrates a schematic cross-sectional view of an embodiment of the sub-pixel taken along line A-A′ of FIG. 5.

In an embodiment, the sub-pixel SPX may include a substrate SUB, a display element area DPA, and a light conversion area LCA. The display element area DPA and the light conversion area LCA may be sequentially provided and/or formed on the substrate SUB. The light conversion area LCA may overlap the display element area DPA when viewed in a cross-sectional view.

In an embodiment, the display element area DPA may include a passivation layer PVX, a via layer VIA, a data line DL, wall patterns WP, first and second alignment electrodes ALE1 and ALE2, a (1-1)-th light emitting element LD1, and insulating layers INS1 to INS3.

In an embodiment, the passivation layer PVX may be entirely disposed on the substrate SUB. The passivation layer PVX may include an inorganic material. The passivation layer PVX may be provided as a single film, or may be provided as a multifilm of at least two or more films. The data line DL of the sub-pixel SPX may be disposed on the passivation layer PVX. The data line DL may overlap the second alignment electrode ALE2 when viewed in a cross-sectional view.

In an embodiment, the via layer VIA may be entirely disposed on the passivation layer PVX to cover the data line DL. The via layer VIA may include an organic material and may provide a planar surface at the upper portion thereof.

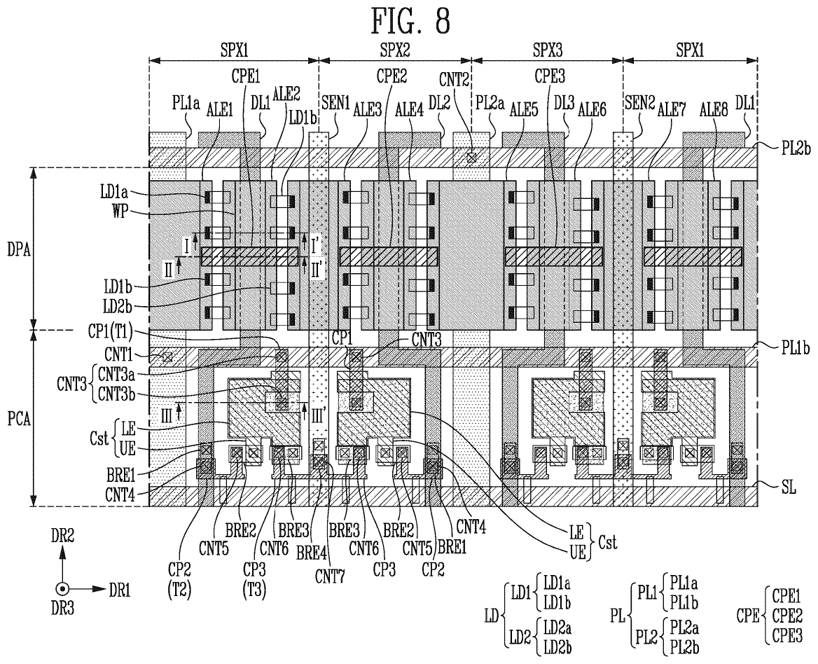

In an embodiment, the display element area DPA may not overlap components (for example, the transistors T1 to T3 in FIG. 2A or FIG. 2B) of a pixel circuit (for example, the pixel circuit PXC in FIG. 2A or FIG. 2B) and a pixel circuit area (for example, a pixel circuit area PCA in FIG. 8) in which the capacitor Cst is disposed, when viewed in a cross sectional view.

The wall patterns WP, the first and second alignment electrodes ALE1 and ALE2, the (1-1)-th light emitting element LD1, the first pixel electrode PE1, the (1-1)-th middle electrode CNEa, and the insulating layers INS1 to INS3 may be provided on the via layer VIA.

The wall patterns WP may be disposed on the via layer VIA. Each of the wall patterns WP may include a curved surface having a cross section of a semi-elliptic shape or a semi-circular shape (or semi-spherical shape) of which width is narrowed from a surface of the via layer VIA toward an upper portion thereof along the third direction DR3. However, embodiments are not limited thereto, and each of the wall patterns WP may have a cross-section of a trapezoidal shape of which width is narrowed from a surface (for example, an upper surface) of the via layer VIA toward an upper portion thereof along the third direction DR3. When viewed in a cross-sectional view, the shape of each of the wall patterns WP is not limited to the above-described embodiments, and the shape thereof may be variously changed within a range in which the first bank may improve efficiency of light emitted from the (1-1)-th light emitting element LD1.

The wall patterns WP may include an inorganic material and/or an organic material, and may be configured of a single film or a multi-film. In some embodiments, the wall patterns WP may be omitted. For example, a structure corresponding to the wall patterns WP may be formed in the via layer VIA.

The first and second alignment electrodes ALE1 and ALE2 may be disposed on the via layer VIA and the wall patterns WP. The first and second alignment electrodes ALE1 and ALE2 may be disposed on the wall patterns WP. When viewed in a cross-sectional view, the first and second alignment electrodes ALE1 and ALE2 may have surface profiles respectively corresponding to the shapes of the wall patterns WP.

Each of the first and second alignment electrodes ALE1 and ALE2 may include a conductive material having a constant reflectivity to allow light emitted from the (1-1)-th light emitting element LD1 to be directed in an image display direction (for example, the third direction DR3) of the display device. The first and second alignment electrodes ALE1 and ALE2 may be configured of a single film or a multi-film.

The first and second alignment electrodes ALE1 and ALE2 may be used as alignment electrodes for aligning the (1-1)-th light emitting element LD1 in the manufacturing process of the display device.

Referring to FIG. 5 and FIG. 6, only the first and second alignment electrodes ALE1 and ALE2 except for the third alignment electrode ALE3 are illustrated in FIG. 6, but the third alignment electrode ALE3 may be spaced apart from each other in the first direction DR1 of the second alignment electrode ALE2, and the (1-2)-th light emitting element LD2 may be disposed between the second and third alignment electrodes ALE2 and ALE3.

The first insulating layer INS1 may be disposed on the via layer VIA to cover at least a portion of the first and second alignment electrodes ALE1 and ALE2. The first insulating layer INS1 may be disposed between the first and second alignment electrodes ALE1 and ALE2, and may prevent a short circuit between the first alignment electrode ALE1 and the second alignment electrode ALE2. The first insulating layer INS1 may include an organic material or an inorganic material.

The (1-1)-th light emitting element LD1 may be disposed on the first insulating layer INS1. In an embodiment, so that a first end portion of the (1-1)-th light emitting element LD1 (for example, the first end portion EP1 in FIG. 3) is directed toward the first alignment electrode ALE1 and a second end portion of the (1-1)-th light emitting element LD1 (for example, the second end portion EP2 in FIG. 3) is directed toward the second alignment electrode ALE2, the (1-1) light emitting element LD1 may be aligned between the first alignment electrode ALE1 and the second alignment electrode ALE2.

The second insulating layer INS2 (or a second insulating pattern) may be disposed on the (1-1)-th light emitting element LD1. The second insulating layer INS2 may be disposed on a portion of the upper surface of the (1-1)-th light emitting element LD1 so that the first end portion and the second end portion of the (1-1)-th light emitting element LD1 are exposed to the outside. In some embodiments, the second insulating layer INS2 may also be disposed on the first insulating layer INS1.

The second insulating layer INS2 may include an inorganic material or an organic material according to the design conditions of the display device including the (1-1)-th light emitting element LD1. After the alignment of the (1-1)-th light emitting element LD1 on the first insulating layer INS1 is completed, the second insulating layer INS2 may be disposed on the (1-1)-th light emitting element LD1, thereby preventing the (1-1)-th light emitting element LD1 from being separated from the aligned position. In case that there is a gap (or space) between the first insulating layer INS1 and the (1-1)-th light emitting element LD1 before the second insulating layer INS2 is formed, the gap may be filled with the second insulating layer INS2 in the process of forming the second insulating layer INS2.

In an embodiment, the first pixel electrode PE1 may be disposed on the second insulating layer INS2. The first pixel electrode PE1 may directly contact the first end portion of the (1-1)-th light emitting element LD1. The first pixel electrode PE1 may be disposed on the first alignment electrode ALE1.

In an embodiment, the third insulating layer INS3 may be disposed on the second insulating layer INS2 and the first pixel electrode PE1 to cover the second insulating layer INS2 and the first pixel electrode PE1. The third insulating layer INS3 may be disposed such that an end portion and an edge of the second insulating layer INS2 are in contact with each other so that the second end portion of the (1-1)-th light emitting element LD1 is exposed. The third insulating layer INS3 may include an inorganic material.

In an embodiment, the (1-1)-th middle electrode CNEa may be disposed on the third insulating layer INS3. The (1-1)-th middle electrode CNEa may be in direct contact with the second end portion of the (1-1)-th light emitting element LD1. The (1-1)-th middle electrode CNEa may be disposed on the second alignment electrode ALE2.

FIG. 6 illustrates that the first pixel electrode PE1 and the (1-1)-th middle electrode CNEa are disposed on different layers, and that the third insulating layer INS3 may be between the first pixel electrode PE1 and the (1-1)-th middle electrode CNEa, but the disclosure is not limited thereto. For example, the first pixel electrode PE1 and the (1-1)-th middle electrode CNEa may be disposed on the same layer (for example, the second insulating layer INS2) through the same process.

The light conversion area LCA may be provided and/or formed on the display element area DPA. The light conversion area LCA may include a color conversion layer CCL and a color filter CF.

A bank (for example, the bank BNK in FIG. 5) (not shown) may be disposed on the third insulating layer INS3. The bank may have a trapezoidal cross-section in which the width of the third insulating layer INS3 decreases from a surface (for example, an upper surface) toward the upper portion along the third direction DR3.

The color conversion layer CCL may be disposed on the display element area DPA (or the (1-1)-th light emitting elements LD1) in the area surrounded by the bank.

The color conversion layer CCL may include color conversion particles QD (or wavelength conversion particles) corresponding to a specific color. As an example, the color conversion layer CCL may include color conversion particles QD that convert light of a first color (or a first wavelength band) incident from the light emitting element LD into light of a second color (or a specific color or a second wavelength band) and emit the light.

In case that the sub-pixel is a red pixel (or a red sub-pixel), the sub-pixel SPX may include color conversion particles of a red quantum dot that converts light of a first color emitted from the (1-1)-th light emitting element LD1 into light of a second color (for example, red light).

In case that the sub-pixel is a green pixel (or a green sub-pixel), the sub-pixel SPX may include color conversion particles of a green quantum dot that converts light of a first color emitted from the (1-1)-th light emitting element LD1 into light of a second color (for example, green light).

In case that the sub-pixel is a blue pixel (or a blue sub-pixel), the sub-pixel SPX may include color conversion particles of a blue quantum dot that converts light of a first color emitted from the (1-1)-th light emitting element LD1 into light of a second color (for example, blue light). In case that the sub-pixel SPX is a blue pixel and the (1-1)-th light emitting element LD1 emits blue-based light, the sub-pixel SPX may include a light scattering layer including light scattering particles SCT. An above-described light scattering layer may be omitted according to embodiments. According to another embodiment, in case that the sub-pixel SPX is a blue pixel, a transparent polymer may be provided instead of the color conversion layer CCL.

A first capping layer CAP1 may seal (or cover) the color conversion layer CCL. The first capping layer CAP1 may be disposed between a low refractive index layer LRL and the color conversion layer CCL. The first capping layer CAP1 may prevent impurities such as moisture or air from penetrating from the outside. For example, the first capping layer CAP1 may include at least one of a silicon nitride (SiNₓ), a silicon oxide (SiOₓ), a silicon oxynitride (SiOₓN_{y}), and an aluminum oxide (AlOₓ).

The low refractive index layer LRL may be disposed between the first capping layer CAP1 and a second capping layer CAP2. The low refractive index layer LRL may improve light efficiency by recycling light provided from the color conversion layer CCL. To this end, the low refractive index layer LRL may have a lower refractive index than the color conversion layer CCL. In an embodiment, the low refractive index layer LRL may include a base resin and hollow particles dispersed in the base resin. The hollow particles may include hollow silica particles. The hollow particle may be a pore formed by a porogen, but is not necessarily limited thereto. The low refractive index layer LRL may include at least one of a zinc oxide (ZnOₓ), a titanium oxide (TiOₓ), and a nano silicate particle, but is not necessarily limited thereto.

In an embodiment, the second capping layer CAP2 may be disposed on the low refractive index layer LRL. The second capping layer CAP2 may prevent impurities such as moisture or air from penetrating from the outside. The second capping layer CAP2 may include at least one of a silicon nitride (SiNₓ), a silicon oxide (SiOₓ), a silicon oxynitride (SiOₓN_{y}), and an aluminum oxide (AlOₓ).

In an embodiment, the color filter CF may be disposed on the second capping layer CAP2. The color filter CF may include a color filter material that selectively transmits light of a specific color converted by the color conversion layer CCL. In an embodiment, in case that the sub-pixel SPX is a red pixel, the color filter CF disposed on the color conversion layer CCL may be a red color filter. In case that the sub-pixel SPX is a green pixel, the color filter CF disposed on the color conversion layer CCL may be a green color filter. In case that the sub-pixel SPX is a blue pixel, the color filter CF disposed on the color conversion layer CCL may be a blue color filter.

An overcoat layer OC may be disposed on the color filter CF. The overcoat layer OC may include an inorganic material or an organic material. The overcoat layer OC may entirely cover the components disposed thereunder to prevent moisture or water from flowing into the color filter CF and the display element area DPA from the outside. In an embodiment, the overcoat layer OC may be formed of multiple layers. For example, the overcoat layer OC may include at least two layers of inorganic films and at least one layer of organic film interposed between the at least two layers of inorganic films. However, the material and/or structure of the overcoat layer OC may be variously changed.

In an above-described embodiment, it has been described that the color conversion layer CCL is directly formed on the display element area DPA, but the disclosure is not limited thereto. In some embodiments, the color conversion layer CCL may be formed on a separate substrate to be coupled to the display element area DPA through an adhesive material. For example, the adhesive material may be an optically clear adhesive layer, but is not limited thereto.

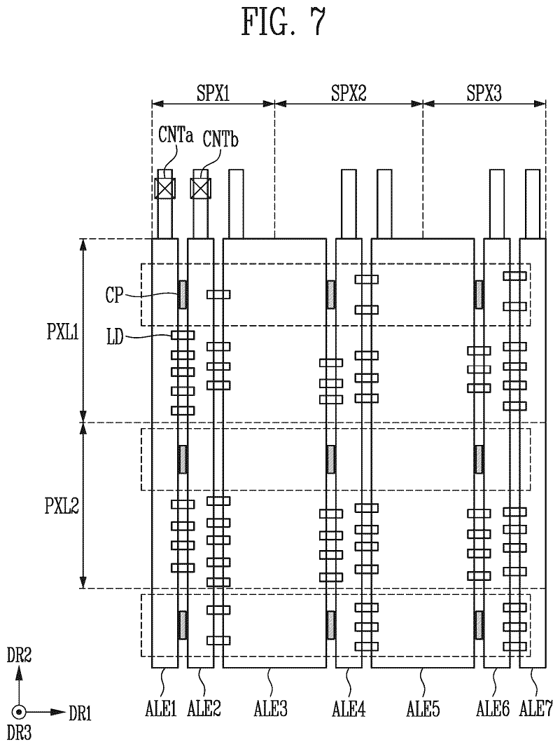

FIG. 7 illustrates a comparative example of disposition of light emitting elements according to a position of a conductive pattern of a pixel circuit.

Referring to FIG. 7, the display device may include alignment electrodes ALE1 to ALE7 and light emitting elements LD to configure pixels.

The alignment electrodes ALE1 to ALE7 may be spaced apart from each other in the first direction DR1.

The first and second pixels PXL1 and PXL2 may be spaced apart from each other in the second direction DR2. The first to third sub-pixels SPX1 to SPX3 included in each of the first and second pixels PXL1 and PXL2 may be spaced apart from each other in the first direction DR1.

The first and second pixels PXL1 and PXL2 may share mutually the alignment electrodes ALE1 to ALE7. The first sub-pixel SPX1 of the first pixel PXL1 may share the first to third alignment electrodes ALE1 to ALE3 with the first sub-pixel SPX1 of the second pixel SPX2.

The alignment electrodes ALE1 to ALE7 may be electrodes for aligning the light emitting element LD. For example, an electric field is formed between (or on) the alignment electrodes ALE1 to ALE7, and the light emitting elements LD may be aligned on the alignment electrodes ALE1 to ALE7 based on the electric field. For example, the light emitting elements LD may be moved (or rotated) by a force (for example, dielectrophoresis (DEP) force) according to the electric field to be aligned (or disposed) on the alignment electrodes ALE1 to ALE7.

A pixel circuit including multiple transistors and a capacitor may be disposed below the alignment electrodes ALE1 to ALE7 where the light emitting element LD is disposed. As the pixel circuit may be disposed below the alignment electrodes ALE1 to ALE7, the conductive pattern CP may overlap the area between the alignment electrodes ALE1 to ALE7.

In case that the conductive pattern CP is disposed in the lower area between the alignment electrodes ALE1 to ALE7, the signal of the electric field formed between the alignment electrodes ALE1 to ALE7 may be distorted by the conductive pattern CP during the alignment process. Accordingly, in the alignment process of the light emitting element LD, even if an electric field is applied to the alignment electrodes ALE1 to ALE7, the light emitting elements LD may not be disposed on the alignment electrodes ALE1 and ALE7 overlapping the conductive pattern CP. For example, in case that the conductive pattern CP is disposed in the lower area between the alignment electrodes ALE1 to ALE7, it may be difficult to secure light emitting efficiency due to the non-disposition of the light emitting elements compared to the display area.

In the alignment process, in order to secure the light emitting elements LD that are disposed on the alignment electrodes ALE1 to ALE7 and configure an effective light source, distortion of the signal of the electric field formed between the alignment electrodes ALE1 to ALE7 should be minimized, to this end, the lower area of the alignment electrodes ALE1 to ALE7 and the components of the pixel circuit may not overlap, particularly, in case that the conductive pattern CP does not overlap the lower area between the alignment electrodes AEL1 to ALE7, which are most likely to affect the electric field formed between the alignment electrodes ALE1 to ALE7, it is possible to minimize distortion of the signal of the electric field formed between the alignment electrodes ALE1 to ALE7.

The conductive pattern CP may be an electrode configuring a storage capacitor of a pixel circuit, but is not limited thereto. For example, the conductive pattern CP may include a first terminal (source electrode) or a second terminal (drain electrode) of a transistor.

FIG. 8 illustrates a schematic top plan view of an embodiment of a display area of FIG. 1.

FIG. 8 illustrates a layout diagram of an embodiment of a pixel that may be included in the display device. Referring to FIG. 8, the pixel PXL may include the first to third sub-pixels SPX1 to SPX3 spaced apart from each other in the first direction DR1, and the pixel circuit of the first sub-pixel SPX1 (for example, the pixel circuit PXC of FIG. 2A or FIG. 2B) may have a structure that is symmetrical to the pixel circuit of the second sub-pixel SPX2 in the first direction DR1, and the third sub-pixel SPX3 may have a structure that is substantially the same as or similar to that of the first sub-pixel SPX1. Accordingly, the configuration of the first to third sub-pixels SPX1 to SPX3 will be described based on the first sub-pixel SPX1, and redundant descriptions will not be repeated.

In an embodiment, the first to third sub-pixels SPX1 to SPX3 may include a display element area DPA and a pixel circuit area PCA. In an embodiment, the display element area DPA may be an area in which light emitting elements LD that emit light are disposed. In an embodiment, the pixel circuit area PCA may include multiple transistors and signal wires connected to the transistors. In each of the transistors, a semiconductor pattern, a gate electrode, a source electrode, and a drain electrode may be stacked on each other. An insulating layer may be disposed between one or more of the semiconductor pattern, the gate electrode, the source electrode, and the drain electrode. In an embodiment, the pixel circuit area PCA may not overlap the display element area DPA in a plan view. In an embodiment, the pixel circuit area PCA may be spaced apart from the display element area DPA in the second direction DR2.

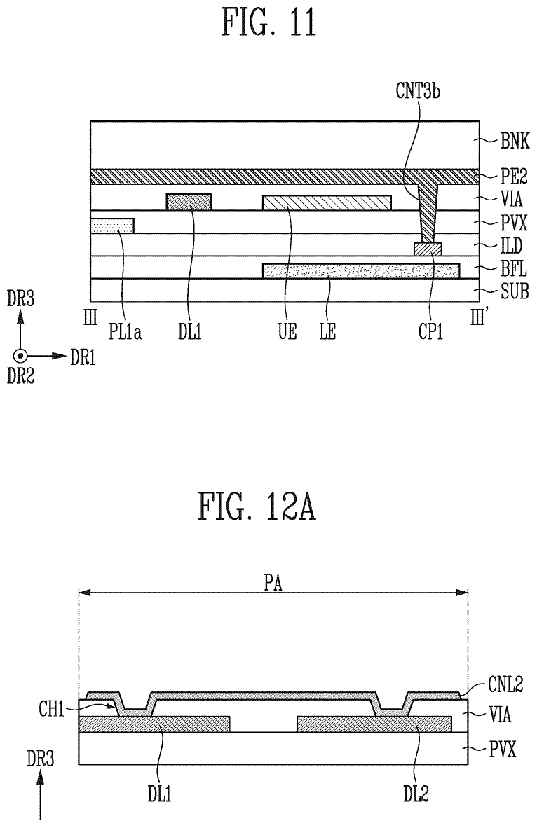

In an embodiment, the first vertical power line PL1a, the first data line DL1, the first sensing line SEN1, the second data line DL2, the second vertical power line PL2a, the third data line DL3, and the second sensing line SEN2 may respectively extend in the second direction DR2 and may be arranged along the first direction DR1. In an embodiment, the first and second vertical power lines PL1a and PL2a and the first and second sensing lines SEN1 and SEN2 may be disposed on a first conductive layer (for example, the interlayer insulating layer ILD in FIG. 11), and the first to third data lines DL1 to DL3 may be disposed on a second conductive layer (for example, the passivation layer PVX in FIG. 11), which may be different from the first conductive layer. However, the disclosure is not limited thereto, and the first to third data lines DL1 to DL3 may be disposed on the first conductive layer.

In an embodiment, the second horizontal power line PL2b, the first horizontal power line PL1b, and the scan line SL may respectively extend in the first direction DR1, and may be arranged along the second direction DR2. In an embodiment, the first horizontal power line PL1b, the second horizontal power line PL2b, and the scan line SL may be disposed on a third conductive layer (for example, the buffer layer BFL in FIG. 11).

In an embodiment, the first power line PL1 may receive a voltage of the first driving power source VDD. The first vertical power line PL1a and the first horizontal power line PL1b may be electrically connected to each other through the first contact hole CNT1.

In an embodiment, the second power line PL2 may receive a voltage of the second driving power source VSS. The second vertical power line PL2a and the second horizontal power line PL2b may be electrically connected to each other through the second contact hole CNT2.

In an embodiment, the first vertical power line PL1a and the second vertical power line PL2a may extend from the display element area DPA to the pixel circuit area PCA. In an embodiment, the first vertical power line PL1a may be disposed on a side of the first sub-pixel SPX1. In an embodiment, the first vertical power line PL1a may overlap the first alignment electrode ALE1 disposed in the display element area DPA. The second vertical power line PL2a may be disposed between the second sub-pixel SPX2 and the third sub-pixel SPX3. The second vertical power line PL2a may overlap the fifth alignment electrode ALE5 disposed in the display element area DPA.

In an embodiment, the first and second sensing lines SEN1 and SEN2 may extend from the display element area DPA to the pixel circuit area PCA. The first and second sensing lines SEN1 and SEN2 may receive a voltage of the initialization power source. The first sensing line SNE1 may be electrically connected to the third transistor T3 of each of the first and second sub-pixels SPX1 and SPX2. The second sensing line SEN2 may be electrically connected to the third transistor T3 of the third sub-pixel SPX3 and the third transistor T3 of the first sub-pixel SPX1 of the pixel adjacent to the pixel PXL in the first direction DR1.

In an embodiment, the first to third data lines DL1 to DL3 may extend from the display device area DPA to the pixel circuit area PCA. The first data line DL1 may overlap the second alignment electrode ALE2 of the first sub-pixel SPX1. The second data line DL2 may overlap the fourth alignment electrode ALE4 of the second sub-pixel SPX2. The third data line DL3 may overlap the sixth alignment electrode ALE6 of the third sub-pixel SPX3. Each of the first to third data lines DL1 to DL3 may receive a data signal. The first data line DL1 may be electrically connected to the second transistor T2 of the first sub-pixel SPX1. The second data line DL2 may be electrically connected to the second transistor T2 of the second sub-pixel SPX2. The third data line DL3 may be electrically connected to the second transistor T2 of the third sub-pixel SPX3.

In an embodiment, in a process step (hereinafter referred to as an alignment process) in which the light emitting elements LD are aligned on the alignment electrodes ALE1 to ALE7, the same alignment signal as the alignment signal applied to the second, fourth, and sixth alignment electrodes ALE2, ALE4, and ALE6 may be applied to the first to third data lines DL1 to DL3. For example, as the same alignment signal as the alignment signal applied to the alignment electrodes overlapping the first to third data lines DL1 to DL3 is applied to the first to third data lines DL1 to DL3, in the alignment process, the light emitting elements LD may reduce distortion of the alignment signal caused by the first to third data lines DL1 to DL3.

In an embodiment, the first sensing line SEN1 may be disposed between the first and second data lines DL1 and DL2 in a plan view. The second sensing line SNE2 may be disposed between the third data line DL3 and the first data line DL1 of the first sub-pixel SPX1 of the pixel adjacent to the pixel PXL in the first direction DR1. In an embodiment, the first sensing line SEN1 may overlap the third alignment electrode ALE3. The second sensing line SEN2 may overlap the seventh alignment electrode ALE7.

In an embodiment, in the display element area DPA of the first sub-pixel SPX1, the first to third alignment electrodes ALE1 to ALE3 may extend in the second direction DR2 and may be sequentially disposed in the first direction DR1. In an embodiment, in the display element area DPA of the second sub-pixel SPX2, the third to fifth alignment electrodes ALE3 to ALE5 may extend in the second direction DR2 and may be sequentially disposed in the first direction DR1. In an embodiment, in the display element area DPA of the third sub-pixel SPX3, the fifth to seventh alignment electrodes ALE5 to ALE7 may extend in the second direction DR2 and may be sequentially disposed in the first direction DR1.

In an embodiment, the first sub-pixel SPX1 and the second sub-pixel SPX2 may share the third alignment electrode ALE3, and the second sub-pixel SPX2 and the third sub-pixel SPX3 may share the fifth alignment electrode ALE5.

In an embodiment, the light emitting elements LD may be disposed on (or between) the first to seventh alignment electrodes ALE1 to ALE7.

In an embodiment, the pattern electrodes CPE may be disposed in the display element area DPA of the first to third sub-pixels SPX1 to SPX3. In an embodiment, the pattern electrodes CPE may include first to third pattern electrodes CPE1 to CPE3. The first to third pattern electrodes CPE1 to CPE3 may extend in the first direction DR1 and may be spaced apart from each other along the first direction DR1. In an embodiment, the first pattern electrode CPE1 may extend in the first direction DR1 in the display element area DPA of the first sub-pixel SPX1, and in a plan view, they may overlap the first to third alignment electrodes ALE1 to ALE3. In an embodiment, the second pattern electrode CPE2 may extend in the first direction DR1 in the display element area DPA of the second sub-pixel SPX2, and in a plan view, they may overlap the third to fifth alignment electrodes ALE3 to ALE5. In an embodiment, the third pattern electrode CPE2 may extend in the first direction DR1 in the display element area DPA of the third sub-pixel SPX3, and in a plan view, they may overlap the fifth to seventh alignment electrodes ALE5 to ALE7.

In an embodiment, the light emitting element LD may not be disposed on the alignment electrodes ALE1 to ALE7 that overlap the pattern electrode CPE. In an embodiment, the first pattern electrode CPE1 of the first sub-pixel SPX1 may overlap the area between the first and second alignment electrodes ALE1 and ALE2 and the area between the second and third alignment electrodes ALE2 and ALE3 in a plan view. In an embodiment, the light emitting element LD may not be disposed on the first to third alignment electrodes ALE1 to ALE3 that overlap the first pattern electrode CPE1.

In an embodiment, the light emitting elements LD may include the (1-1)-th light emitting elements LD1 and the (1-2)-th light emitting elements LD2. The (1-1)-th light emitting element LD1 may be disposed between the first and second alignment electrodes ALE1 and ALE2. The (1-2)-th light emitting element LD2 may be disposed between the second and third alignment electrodes ALE2 and ALE3.

In an embodiment, the (1-1)-th light emitting element LD1 may include a (1-1a)-th light emitting element LD1a disposed in the second direction DR2 (or at an upper side) and a (1-1b)-th light emitting element LD1b disposed in a direction (or at a lower side) opposite to the second direction DR2, with respect to the first pattern electrode CPE1. In an embodiment, the (1-2)-th light emitting element LD2 may include a (1-2a)-th light emitting element LD2a disposed in the second direction DR2 (or at an upper side) and a (1-2b)-th light emitting element LD2b disposed in a direction (or at a lower side) opposite to the second direction DR2, with respect to the first pattern electrode CPE1. In an embodiment, in case that the first sub-pixel SPX1 has 4 serial sub-pixels, the (1-1a)-th light emitting element LD1a may correspond to the first light emitting element (for example, the first light emitting element LDa in FIG. 2B). The (1-1b)-th light emitting element LD1b may correspond to the second light emitting element (for example, the second light emitting element LDb in FIG. 2B). The (1-2a)-th light emitting element LD2a may correspond to the fourth light emitting element (for example, the fourth light emitting element LDd in FIG. 2B). The (1-2b)-th light emitting element LD2b may correspond to the third light emitting element (for example, the third light emitting element LDc in FIG. 2B).

In another embodiment, the pattern electrode CPE may be omitted. The light emitting elements LD may be uniformly disposed between the alignment electrodes ALE1 to ALE7 without an area in which the light emitting elements LD are not disposed in an area between the alignment electrodes ALE1 to ALE7.

In an embodiment, the pixel circuit area PCA of the first to third sub-pixels SPX1 to SPX3 may include first to third connection patterns CP1 to CP3 and a capacitor Cst.

In an embodiment, the first data line DL1 may extend from the display element area DPA to the pixel circuit area PCA to be disposed adjacent to a side of the capacitor Cst. A portion of the first data line DL1 may overlap the first horizontal power line PL1b.

In an embodiment, the capacitor Cst may be spaced apart from the first horizontal power line PL1b in the second direction DR2.

In an embodiment, the first connection pattern CP1 may configure the first transistor T1. The first connection pattern CP1 may correspond to the semiconductor pattern of the first transistor T1. In an embodiment, an end of the first connection pattern CP1 may be electrically connected to the first horizontal power line PL1b through the (3-1)-th contact hole CNT3a. Another end of the first connection pattern CP1 may be electrically connected to the pixel electrode through the (3-2)-th contact hole CNT3b.

In an embodiment, the second connection pattern CP2 may configure the second transistor T2. The second connection pattern CP2 may correspond to the semiconductor pattern of the second transistor T2. The second connection pattern CP2 may be spaced apart from the first connection pattern CP1 in a diagonal direction (for example, a direction between the first direction DR1 and the second direction DR2), and may extend in the first direction DR1. In an embodiment, an end of the second connection pattern CP2 may be electrically connected to the first data line DL1 through the first bridge electrode BRE1 and the fourth contact portion CNT4. Another end of the second connection pattern CP2 may be electrically connected to the upper electrode UE of the capacitor Cst through the second bridge pattern BRE2 and the fifth contact portion CNT5.

In an embodiment, the third connection pattern CP3 may configure the third transistor T3. The third connection pattern CP3 may correspond to the semiconductor pattern of the third transistor T3. The third connection pattern CP3 may be spaced apart from the second connection pattern CP2 in the first direction DR1, and may extend in the first direction DR1. In an embodiment, an end of the third connection pattern CP3 may be electrically connected to the lower electrode LE of the capacitor Cst through the third bridge electrode BRE3 and the sixth contact CNT6.

In an embodiment, the scan line SL may be spaced apart from the capacitor Cst in a direction opposite to the second direction DR2, and may extend in the first direction DR1. The first to third sub-pixels SPX1 to SPX3 may respectively configure gate electrodes of the second and third transistors T2 and T3.

The display device according to the embodiments of the disclosure may overlap the alignment electrodes so that the data lines DL1 to DL3 of each of the first to third sub-pixels SPX1 to SPX3 may not be exposed through the space between the alignment electrodes ALE1 to ALE7, so that distortion of an electric field formed between the alignment electrodes may be minimized in the alignment process. Accordingly, the display device may improve light emitting efficiency as the light emitting elements LD may be uniformly disposed between the alignment electrodes ALE1 to ALE7.

In the display device according to the embodiments, by preventing overlapping the display element area DPA in which the light emitting elements LD are disposed, the pixel circuit area PCA in which the transistors T1 to T3 and the capacitor Cst are disposed, in the alignment process, distortion of the electric field formed between the alignment electrodes ALE1 to ALE7 by the transistors T1 to T3 and the capacitor Cst that configure the pixel circuit may be minimized (or improved). Accordingly, the display device may secure light emitting efficiency.

The display device according to the embodiments may dispose the pattern electrode CPE across the alignment electrodes ALE1 to ALE7 in the display element area DPA to more efficiently form a series stage including the light emitting elements LD of the first to third sub-pixels SPX1 to SPX3.

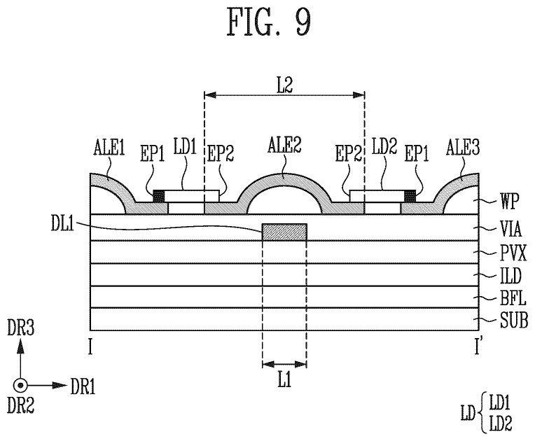

FIG. 9 illustrates a schematic cross-sectional view taken along line I-I′ of FIG. 8.

Referring to FIGS. 8 and 9, a substrate SUB, a buffer layer BFL, an interlayer insulating layer ILD, a passivation layer PVX, and a via layer VIA may be included in the display element area DPA of each of the first to third sub-pixels SPX1 to SPX3. The buffer layer BFL, the interlayer insulating layer ILD, the passivation layer PVX, and the via layer VIA may be sequentially disposed on the substrate SUB.

In an embodiment, the first data line DL1 may be disposed on the passivation layer PVX. The via layer VIA may be disposed on the passivation layer PVX to cover the first data line DL1.

In an embodiment, the first to third alignment electrodes ALE1 to ALE3 may be spaced apart from each other in the first direction DR1 on the via layer VIA.

In an embodiment, the (1-1)-th light emitting element LD1 may be disposed between the first and second alignment electrodes ALE1 and ALE2. The (1-2)-th light emitting element LD2 may be disposed between the second and third alignment electrodes ALE2 and ALE3.

In an embodiment, the first data line DL1 may overlap the second alignment electrode ALE2 when viewed in a cross-sectional view. In an embodiment, the first data line DL1 may not overlap the area between the first and second alignment electrodes ALE1 and ALE2 and the area between the second and third alignment electrodes ALE2 and ALE3. In an embodiment, a length of a first width L1 of the first data line DL1 in the first direction DR1 may be equal to or smaller than a length of a second width L2 of the second alignment electrode ALE2 in the first direction DR1. Since the first width L1 of the first data line DL1 is equal to or smaller than the second width L2 of the second alignment electrode ALE2, the influence on the electric field formed between the first to third alignment electrodes ALE1 to ALE3 in the alignment process may be minimized.

In an embodiment, the first to third alignment electrodes ALE1 to ALE3 and the first data line DL1 may be supplied (provided) with a first alignment signal or a second alignment signal different from the first alignment signal in a process in which the light emitting elements LD are aligned, respectively.

In an embodiment, the first alignment signal and the second alignment signal may have different waveforms, potentials, and/or phases. The first alignment signal may be a ground signal, and the second alignment signal may be an AC signal. However, the disclosure is not necessarily limited to the example described above. For example, the first alignment signal may be an AC signal, and the second alignment signal may be a ground signal.

In an embodiment, the first alignment signal may be applied to the first and third alignment electrodes ALE1 and ALE3. The second alignment signal may be applied to the second alignment electrode ALE2 and the first data line DL1.

In an embodiment, the first end portion EP1 of the (1-1)-th light emitting elements LD1 may be adjacent to the first alignment electrode ALE1. The second end portion EP2 of the (1-1)-th light emitting elements LD1 may be adjacent to the second alignment electrode ALE2.

In an embodiment, the first end portion EP1 of the (1-2)-th light emitting elements LD2 may be adjacent to the third alignment electrode ALE3. The second end portion EP2 of the (2-2)-th light emitting elements LD1 may be adjacent to the second alignment electrode ALE2.

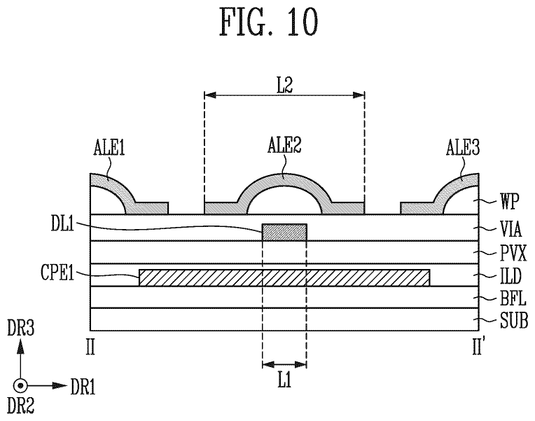

FIG. 10 illustrates a schematic cross-sectional view taken along line II-II′ of FIG. 8.

Referring to FIG. 8 and FIG. 10, the first pattern electrode CPE1 may be disposed on the buffer layer BFL. However, the disclosure is not limited thereto, and the first pattern electrode CPE1 may be disposed on the interlayer insulating layer ILD. In an embodiment, the first pattern electrode CPE1 may configure the bottom metal layer of the first transistor T1, but is not limited thereto, and may form the gate electrode, the source electrode, or the drain electrode of the first transistor T1.

The first pattern electrode CPE1 may overlap the first to third alignment electrodes ALE1 to ALE3. In an embodiment, the first pattern electrode CPE1 may overlap the lower area between the first to third alignment electrodes ALE1 to ALE3. When viewed on the first to third alignment electrodes ALE1 to ALE3, the first pattern electrode CPE1 may be visually recognized through an area between the first to third alignment electrodes ALE1 to ALE3.

In an embodiment, the light emitting elements LD may not be disposed on the first to third alignment electrodes ALE1 to ALE3 overlapping the first pattern electrode CPE1. In the alignment process of the light emitting elements LD, the first pattern electrode CPE1 may affect the electric field formed on the first to third alignment electrodes ALE1 to ALE3 disposed on the first pattern electrode CPE1.

FIG. 11 illustrates a schematic cross-sectional view taken along line III-III′ of FIG. 8.

Referring to FIG. 11, the lower electrode LE may be disposed on the substrate SUB. The buffer layer BFL may be disposed on the substrate SUB to cover the upper electrode UE.

In an embodiment, the first connection pattern CP1 may be disposed on the buffer layer BFL. The first connection pattern CP1 may overlap the lower electrode LE when viewed in a cross-sectional view. In an embodiment, the interlayer insulating layer ILD may be disposed on the buffer layer BFL to cover the first connection pattern CPL.

In an embodiment, the first vertical power line PL1a may be disposed on the interlayer insulating layer ILD. The passivation layer PVX may be disposed on the interlayer insulating layer ILD to cover the first vertical power line PL1a.

In an embodiment, the first data line DL1 and the upper electrode UE may be disposed on the passivation layer PVX. The first data line DL1 and the upper electrode UE may be spaced apart from each other in the first direction DR1. The upper electrode UE may overlap the lower electrode LE. The via layer VIA may cover the first data line DL1 and the upper electrode UE.

In an embodiment, the second pixel electrode PE2 and the bank BNK may be sequentially disposed on the via layer VIA. The second pixel electrode PE2 may be electrically connected to the first connection pattern CP1 through the (3-2)-th contact hole CNT3b. The (3-2)-th contact hole CNT3b may penetrate the via layer VIA, the passivation layer PVX, and the interlayer insulating layer ILD.

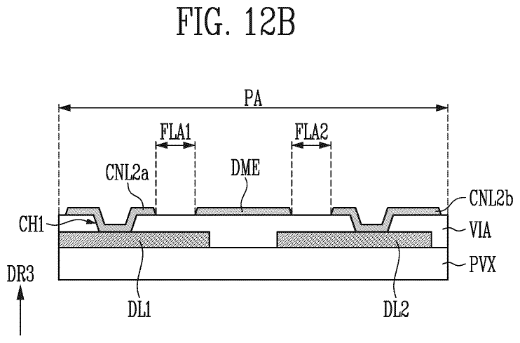

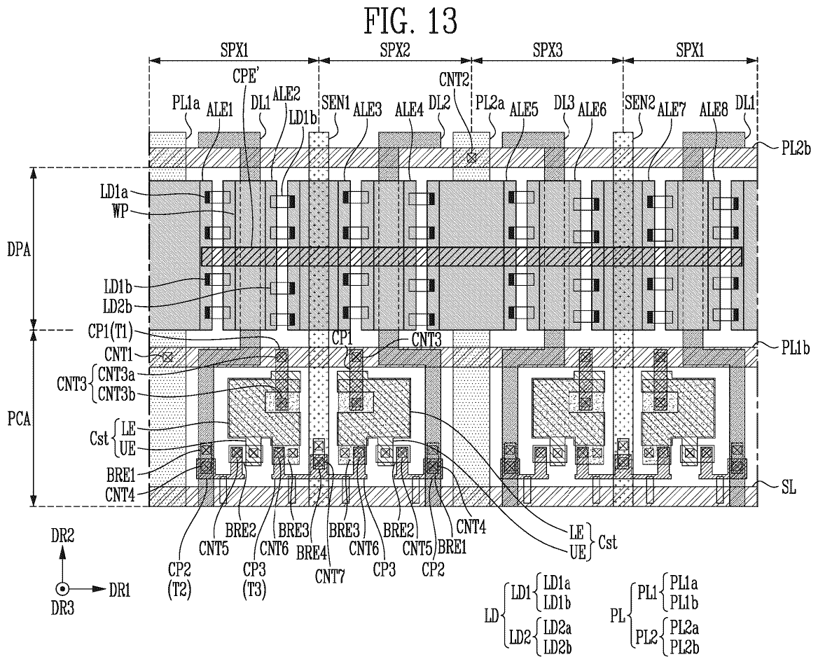

FIG. 12A illustrates a schematic cross-sectional view of an embodiment of a peripheral area of FIG. 1. FIG. 12B illustrates a schematic cross-sectional view of another embodiment of a peripheral area of FIG. 1.

FIG. 12A illustrates an embodiment of the peripheral area PA of the display device before the alignment process during the manufacturing process of the display device, and FIG. 12B illustrates an embodiment of the peripheral area PA of the display device after the alignment process is completed during the manufacturing process of the display device.

Referring to FIG. 5, FIG. 8, and FIG. 12A, the second connection electrode CNL2 may directly contact the data lines DL1 and DL2 through the first contact portion CH1 in the alignment process of the light emitting elements LD during the manufacturing process of the display device. For example, the second connection electrode CNL2 may be electrically connected to the first and second data lines DL1 and DL2 through the first contact portion CH1. In an embodiment, in case that the first alignment signal is applied to the second, fourth, and sixth alignment electrodes ALE2, ALE4, and ALE6 connected to the second connection electrodes CNL2, the same first alignment signal may be applied to the first and second data lines DL1 and DL2. In an embodiment, in the alignment process of the light emitting elements LD, the alignment signals applied to the second alignment electrode ALE2 overlapping the first data line DL1 and the fourth alignment electrode ALE4 overlapping the second data line DL2 may be equally applied to the first and second data lines DL1 and DL2.

Referring to FIG. 5, FIG. 8, and FIG. 12B, after the alignment process of the light emitting elements LD is completed, the second connection electrode CNL2 may be divided into a (2-1)-th partial connection electrode CNL2a, a (2-2)-th partial connection electrode CNL2b, and a dummy electrode DME.

In an embodiment, the area corresponding to the portion from which the second connection electrode CNL2 is removed may be referred to as first and second floating areas FLA1 and FLA2.

In an embodiment, the first floating area FLA1 of the second connection electrode CNL2 may be removed to be separated into the (2-1)-th partial connection electrode CNL2a and the dummy electrode DME. The second floating area FLA2 of the second connection electrode CNL2 may be removed to be separated into the (2-2)-th partial connection electrode CNL2b and the dummy electrode DME.

In an embodiment, the process of removing the area of the second connection electrode CNL2 to separate it into the (2-1)-th partial connection electrode CNL2a, the (2-2)-th partial connection electrode CNL2b, and the dummy electrode DME may form a floating hole by removing a portion of the second alignment electrode ALE2 by emitting laser light to the second connection electrode CNL2.

Referring to FIG. 12B, the floating areas of the second connection electrode CNL2 are shown as the first and second floating areas FLA1 and FLA2, but are not limited thereto. For example, the floating area of the second connection electrode CNL2 may be 1 or 2 or more.

In an embodiment, the dummy electrode DME may be disposed between the first and second data lines DL1 and DL2 extending to the peripheral area PA. In an embodiment, the dummy electrode DME may be in a floating state. For example, the dummy electrode DME may have an island shape that is not connected to other conductive layers (or conductive patterns).

FIG. 13 illustrates a schematic top plan view of another embodiment of a display area of FIG. 1.

In components except for a pattern electrode CPE′, redundant descriptions of components that are the same as or correspond to those shown in FIG. 8 will be omitted.

In an embodiment, the pattern electrode CPE′ may extend in the first direction DR1, and may be integrally disposed across the first to third sub-pixels SPX1 to SPX3. The pattern electrode CPE′ may overlap the first to seventh alignment electrodes ALE1 to ALE7 in a plan view.

In an embodiment, the light emitting elements LD may not be disposed on the alignment electrodes ALE1 to ALE7 that overlap the pattern electrode CPE′.

In an embodiment, the pattern electrode CPE′ may be disposed on a conductive layer different from the conductive layer on which the first and second sensing lines SEN1 and SEN2 are disposed. For example, the pattern electrode CPE′ may be disposed on a substrate (for example, the substrate SUB in FIG. 10) and may form the bottom metal layer of the first transistor T1, but is not limited thereto.

In another embodiment, the pattern electrode CPE′ may be omitted. The light emitting elements LD may be uniformly disposed between the alignment electrodes ALE1 to ALE7 without an area in which the light emitting elements LD are not disposed in an area between the alignment electrodes ALE1 to ALE7.

According to the display device according to the embodiments of the disclosure, by removing (or minimizing) the components of the pixel circuit overlapping the area between the alignment electrodes, distortion of the alignment signal or limitation of the area in which the light emitting elements are aligned may be minimized (or improved), by the configuration of the pixel circuit in the alignment process of the light emitting elements.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the disclosure.

What is claimed is:

1. A display device, comprising:
a substrate including:
a display area; and
a peripheral area disposed on a side of the display area;
a first alignment electrode, a second alignment electrode, and a third alignment electrode that overlap the display area, are spaced apart from each other in a first direction, and extend in a second direction intersecting the first direction;
light emitting elements disposed between the first alignment electrode and the second alignment electrode, and between the second alignment electrode and the third alignment electrode; and
a data line overlapping the second alignment electrode in a plan view and extending in the second direction,
wherein a length of a first width of the data line in the first direction is less than or equal to a length of a second width of the second alignment electrode in the first direction.

2. The display device of claim 1, further comprising:
a pattern electrode that overlaps the first alignment electrode, the second alignment electrode, and the third alignment electrode in a plan view and extends in the first direction.

3. The display device of claim 2, wherein
the light emitting elements do not overlap the pattern electrode in a plan view.

4. The display device of claim 2, wherein
the second alignment electrode and the data line provide a first alignment signal in aligning the light emitting elements, and
the first alignment electrode and the third alignment electrode provide a second alignment signal that is different from the first alignment signal.

5. The display device of claim 2, further comprising:
a passivation layer and a via layer sequentially disposed on the substrate, wherein
the data line is disposed between the passivation layer and the via layer, and
the first alignment electrode, the second alignment electrode, and the third alignment electrode are disposed on the via layer.

6. The display device of claim 5, wherein
the second alignment electrode and the data line extend from the display area to the peripheral area, and
the second alignment electrode and the data line are in direct contact through a contact portion that penetrates the via layer in the peripheral area.

7. The display device of claim 6, further comprising:
a dummy electrode spaced apart from the second alignment electrode in the second direction in the peripheral area.

8. The display device of claim 5, wherein
the display area includes a display element area and a pixel circuit area spaced apart from the display element area in the second direction;
the first alignment electrode, the second alignment electrode, the third alignment electrode, and the light emitting elements are disposed in the display element area; and
a plurality of transistors and a storage capacitor are disposed in the pixel circuit area.

9. The display device of claim 8, further comprising:
a buffer layer and an interlayer insulating layer disposed between the substrate and the passivation layer, wherein
a lower electrode of the storage capacitor is disposed between the substrate and the buffer layer,
an upper electrode of the storage capacitor is disposed between the interlayer insulating layer and the passivation layer, and the pattern electrode is disposed between the buffer layer and the interlayer insulating layer.

10. The display device of claim 8, further comprising:
a first vertical power line that receives a first power source and extends in the second direction;
a first horizontal power line electrically connected to the first vertical power line and extending in the first direction;
a second vertical power line that receives a second power source and extends in the second direction; and
a second horizontal power line electrically connected to the second vertical power line and extending in the first direction,
wherein the first and second alignment electrodes are disposed between the first horizontal power line and the second horizontal power line in a plan view.

11. The display device of claim 10, wherein
the first vertical power line and the second vertical power line are disposed on a different layer from the data line.

12. The display device of claim 10, wherein
the storage capacitor is spaced apart from the first horizontal power line in the second direction.

13. The display device of claim 10, further comprising:
a scan line disposed in the pixel circuit area and extending in the first direction,
wherein the storage capacitor is disposed between the first horizontal power line and the scan line in a plan view.

14. The display device of claim 10, wherein
a portion of the data line overlaps the first horizontal power line in a plan view.

15. A display device, comprising:
a substrate including:
a first sub-pixel; and
a second sub-pixel; and
a display element area disposed on the substrate and including a first sub-pixel and a second sub-pixel that are spaced apart from each other in a first direction,
wherein the display element area includes:
a first alignment electrode, a second alignment electrode, a third alignment electrode, a fourth alignment electrode, and a fifth alignment electrode that are spaced apart from each other in the first direction, and extend in a second direction intersecting the first direction;
light emitting elements disposed between the first alignment electrode and the second alignment electrode, between the second alignment electrode and the third alignment electrode, between the third alignment electrode and the fourth alignment electrode, and between the fourth alignment electrode and the fifth alignment electrode;
a first data line of the first sub-pixel that overlaps the second alignment electrode in a plan view and extends in the second direction; and
a second data line of the second sub-pixel that overlaps the fourth alignment electrode in a plan view and extends in the second direction, and
a length of a first width of the first data line and the second data line in the first direction is less than or equal to a length of a second width of the second alignment electrode and the fourth alignment electrode in the first direction.

16. The display device of claim 15, further comprising:
a pixel circuit area spaced apart from the display element area in the second direction and including a plurality of transistors and a storage capacitor.

17. The display device of claim 16, further comprising:
a first pattern electrode that overlaps the first alignment electrode, the second alignment electrode, and the third alignment electrode in a plan view and that extends in the first direction; and
a second pattern electrode that is spaced apart from the first pattern electrode in the first direction, overlaps the third alignment electrode, the fourth alignment electrode, and the fifth alignment electrode, and that extends in the first direction.

18. The display device of claim 17, wherein
in a plan view, the first pattern electrode and the second pattern electrode do not overlap the light emitting elements.

19. The display device of claim 16, further comprising:
a pattern electrode overlapping the first alignment electrode, the second alignment electrode, the third alignment electrode, the fourth alignment electrode, and the fifth alignment electrode in a plan view and extending in the first direction,
wherein in a plan view, the pattern electrode does not overlap the light emitting elements.

20. The display device of claim 16, wherein
the first sub-pixel includes (1-1)-th light emitting elements overlapping the first alignment electrode and the second alignment electrode and (1-2)-th light emitting elements overlapping the second alignment electrode and the third alignment electrode, and
the second sub-pixel includes (2-1)-th light emitting elements overlapping the third alignment electrode and the fourth alignment electrode and (2-2)-th light emitting elements overlapping the fourth alignment electrode and the fifth alignment electrode.
